(19) United States
(12) Patent Application Publication
(10) Pub. No.: US 2026/0231469 A1
(43) Pub. Date: Aug. 6, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Toshiaki IWAMATSU, Tokyo (JP); Akihiro KOYAMA, Tokyo (JP); Takeshi KITANI, Tokyo (JP); Tomokatsu WATANABE, Tokyo (JP)

(73) Assignee: Mitsubishi Electric Corporation, Tokyo (JP)

(21) Appl. No.: 19/144,985

(22) PCT Filed: Jan. 12, 2023
(86) PCT No.: PCT/JP2023/000592

§ 371 Date: Jul. 1, 2025

(51) Int. Cl. H10D 30/66; H10D 30/01; H10D 62/10; H10D 62/832

(52) U.S. Cl. CPC H10D 30/668; H10D 30/0297; H10D 30/665; H10D 62/109; H10D 62/127; H10D 62/8325

(57) ABSTRACT

An insulated-gate type semiconductor device with a trench structure suppresses degradation in the reliability of a semiconductor device. The semiconductor device includes a source electrode electrically connected to source regions located adjacent to a trench in a first region, and a gate line provided on the upper surface of a gate electrode provided in a trench in a second region. A radius curvature of the gate insulating film provided on the upper corner portion of the trench in the second region is greater than a radius of curvature of the gate insulating film provided on the upper corner portion of the trench in the first region.

### TECHNICAL FIELD

The technique disclosed in the specification of the present application relates to semiconductor technology.

### BACKGROUND ART

Insulated-gate type semiconductor devices such as metal oxide semiconductor field effect transistors (MOSFET) or insulated gate bipolar transistors (IGBT) are widely used as switching elements in power electronic equipment, the switching elements controlling power supply to loads such as motors.

Some of the insulated-gate type semiconductor devices have a trench structure in which gate electrodes are embedded in a semiconductor layer. The insulated-gate type semiconductor devices with a trench structure can improve the channel width and density in an active area as compared with insulated-gate type semiconductor devices with a structure that is not a trench structure and in which gate electrodes are formed on the surface of a semiconductor layer (planar-type semiconductor devices). Accordingly, electrical resistance per unit area becomes low in the ON-state of the semiconductor devices.

Heretofore, in the insulated-gate type semiconductor devices with a trench structure, a termination area provided around the active area includes a gate electrode and a gate insulating film that are formed on the inside of each trench serving as an opening and in the vicinity of the upper corner portion of the trench on the active area side. In this case, when the semiconductor devices are turned on by the application of a gate voltage, an electric field concentrates on the bottom face of the trench and in the vicinity of the upper comer portion of the trench, and this causes insulation deterioration of the gate insulating film on the bottom face of the trench and in the vicinity of the upper corner portion of the trench. As a result, the reliability of the semiconductor devices may degrade.

To solve this problem, a method is known in which a field relieving region with conductivity is provided on the bottom face of a trench in order to relieve an electric field applied to a gate insulating film provided on the bottom face of the trench (e.g., Patent Document 1).

A method is also known in which a structure includes a deep narrow trench in the active area and a shallow wide trench in the termination area, and gate electrodes formed in the trenches in the active area and the termination area are flattened by a subsequent chemical mechanical polishing (CMP) process or by a combination of subsequent CMP and etch-back processes so that the upper corners of the trenches are not covered with the gate electrodes (see, for example, Patent Document 2).

### PRIOR ART DOCUMENTS

### Patent Documents

Patent Document 1: Japanese Unexamined Patent Application Publication (Translation of PCT Application) No. 2001-511315
Patent Document 2: Japanese Unexamined Patent Application Publication (Translation of PCT Application) No. 2006-520091

### SUMMARY

### Problem to be Solved by the Invention

As the method of setting the potentials of gate electrodes, it is necessary to provide gate contacts (contact holes) the gate electrodes that are provided in gate trenches in a cell array. Since the gate trenches in the cell array are formed with minimum processing dimensions, the occurrence of misregistration with contact masks is of concern. Thus, in some cases, the gate contacts may be provided on the upper surface of polysilicon provided in wide trenches in the termination area in order to avoid a situation that the gate contacts are provided within cells.

Even in this case, it is not possible to avoid a situation that the upper corner portion of the trench is covered with polysilicon. This results in the concentration of an electric field on the area of the upper corner portion of the trench that is covered with polysilicon and degrades the reliability of the semiconductor devices due to insulation deterioration of the gate insulating film.

Meanwhile, with the method of providing a field relieving region on the bottom face of a trench, it may not be possible to suppress insulation deterioration in the vicinity of the upper corner portion of the trench. Besides, the method using a CMP process is difficult to employ in practical situations because it becomes necessary to significantly reduce influences such as warpage of a semiconductor substrate, asperities on the surface of the substrate, in-plane thickness uniformity of a film formed on the semiconductor substrate, or asperities on the film affected by particles or any other factor.

Moreover, in the case where the gate insulating film and the gate electrode are deposited continuously by forming a wide trench in the termination area, the gate electrode may be exposed across a large area in a subsequent etch-back process and may decrease in thickness or disappear as a result of etching. This may make unstable the operations of the insulated-gate type semiconductor device (the reliability of the semiconductor device may deteriorate). There are also some cases in which it is not possible to suppress insulation deterioration in the vicinity of the upper corner portion of the trench.

The technique disclosed in the specification of the present application has been made in light of the problems as described above, and it is a technique for suppressing degradation of the reliability of an insulated-gate type semiconductor device with a trench structure.

### Means to Solve the Problem

A semiconductor device according to a first aspect of the technique disclosed in the specification of the present application includes a drift layer of a first conductivity type, a base region of a second conductivity type provided in a surface layer of the drift layer, a plurality of source regions of the first conductivity type provided in a surface layer of the base region, at least one trench extending from an upper surface of the drift layer through the base region to an inside of the drift layer, a protective layer of the second conductivity type provided in the drift layer located under the trench, a gate insulating film provided along an inside of the trench including an upper corner portion of the trench, a gate electrode provided at least in the trench and surround by the gate insulating film, a source electrode electrically connected to the source regions located adjacent to the trench, and a gate line provided on an upper surface of the gate electrode provided in the trench. Among regions partitioned in the trench in plan view, a region where the source electrode is provided is defined as a first region, and a region where the gate line is provided is defined as a second region. The gate insulating film provided on the upper corner portion of the trench in the second region has a greater radius of curvature than the gate insulating film provided on the upper corner portion of the trench in the first region.

### Effects of the Invention

According to at least the first aspect of the technique disclosed in the specification of the present application, it is possible to suppress the concentration of an electric field even with the application of a gate voltage and thereby to suppress the destruction of the gate insulating film.

The object, features, aspects, and advantages relating to the technique disclosed in the specification of the present application will become more apparent from the following detailed description and the accompanying drawings.

### BRIEF DESCRIPTION OF DRAWINGS

FIG. 1 is a plan view schematically showing an example of a configuration of a semiconductor device according to an embodiment.

FIG. 2 is a sectional view showing part of the configuration of the semiconductor device according to the embodiment.

FIG. 3 is a sectional view showing part of the configuration of the semiconductor device according to the embodiment.

FIG. 4 is a plan view showing part of the configuration of the semiconductor device according to the embodiment.

FIG. 5 is a sectional view showing an example of a configuration of a cell portion in the drawing.

FIG. 6 is a sectional view showing an example of a configuration of a gate contact portion in an active area 20 shown in FIG. 3.

FIG. 7 is a diagram showing an example of a method of manufacturing the semiconductor device according to the embodiment.

FIG. 8 is a diagram showing an example of the method of manufacturing the semiconductor device according to the embodiment.

FIG. 9 is a diagram showing an example of the method of manufacturing the semiconductor device according to the embodiment.

FIG. 10 is a diagram showing an example of the method of manufacturing the semiconductor device according to the embodiment.

FIG. 11 is a diagram showing an example of the method of manufacturing the semiconductor device according to the embodiment.

FIG. 12 is a diagram showing an example of the method of manufacturing the semiconductor device according to the embodiment.

FIG. 13 is a diagram showing an example of the method of manufacturing the semiconductor device according to the embodiment.

FIG. 14 is a diagram showing an example of the method of manufacturing the semiconductor device according to the embodiment.

FIG. 15 is a diagram showing an example of the method of manufacturing the semiconductor device according to the embodiment.

FIG. 16 is a diagram showing an example of the method of manufacturing the semiconductor device according to the embodiment.

FIG. 17 is a diagram showing an example of the method of manufacturing the semiconductor device according to the embodiment.

FIG. 18 is a diagram showing an example of the method of manufacturing the semiconductor device according to the embodiment.

FIG. 19 is a plan view schematically showing another example of the configuration of the semiconductor device according to the embodiment.

FIG. 20 is a diagram showing an example of the method of manufacturing the semiconductor device according to the embodiment.

FIG. 21 is a diagram showing an example of the method of manufacturing the semiconductor device according to the embodiment.

FIG. 22 is a diagram showing an example of the method of manufacturing the semiconductor device according to the embodiment.

FIG. 23 is a plan view schematically showing another example of the configuration of the semiconductor device according to the embodiment.

FIG. 24 is a diagram showing an example of the method of manufacturing the semiconductor device according to the embodiment.

FIG. 25 is a diagram showing an example of the method of manufacturing the semiconductor device according to the embodiment.

FIG. 26 is a sectional view schematically showing another example of the configuration of the semiconductor device according to the embodiment.

FIG. 27 is a sectional view schematically showing another example of the configuration of the semiconductor device according to the embodiment.

FIG. 28 is a sectional view schematically showing another example of the configuration of the semiconductor device according to the embodiment.

FIG. 29 is a sectional view schematically showing another example of the configuration of the semiconductor device according to the embodiment.

FIG. 30 is a sectional view schematically showing another example of the configuration of the semiconductor device according to the embodiment.

### DESCRIPTION OF EMBODIMENTS

Embodiments are described hereinafter with reference to the accompanied drawings. While detailed features or the like are also described for the explanation of technology in the following description, they are merely illustrative, and not all of them are absolutely indispensable features that are necessary to implement the embodiments.

The drawings are given in schematic form, and for the sake of convenience, configurations may be omitted or simplified as appropriate in the drawings. Mutual relationships in size and position among configurations or the like shown in different drawings are not always accurate and may be changed as appropriate. To facilitate understanding of the contents of embodiments, cross-hatching may be used in drawings other than sectional views, such as plan views.

In the following description, identical constituent elements are given the same reference signs in the drawings and are assumed to have the same names and functions, Therefore, in some cases, detailed description of such constituent elements may be omitted in order to avoid redundancy.

In the description given in the specification of the present application, unless otherwise specified, phrases such as “include,” “contain,” or “have” are not mutually exclusive expressions that eliminate the possibility of the presence of other constituent elements.

In the description given in the specification of the present application, ordinal numbers such as “first” or “second” may be used in some cases, but they are merely used for the sake of convenience to facilitate understanding of the contents of embodiments and do not intend to impose limitations on any sequence indicated by these ordinal numbers in the embodiments.

In the description given in the specification of the present application, terms such as “upper,” “lower,” “left,” “right,” “side,” “bottom,” “front,” and “back” that mean specific positions or directions may be used in some cases, but these terms are merely used for the sake of convenience to facilitate understanding of the contents of embodiments and does not relate to positions or directions in actual implementation of the embodiments.

In the description given in the specification of the present application, phrases such as “the upper surface of . . . ” or “the lower surface of . . . ” refer to not only the upper or lower surface itself of a target constituent element, but also a state in which any other constituent element may be formed in/on the upper or lower surface of the target constituent element. That is, for example, the phrase “B provided on the upper surface of A” does not eliminate the possibility that another constituent element C exists between A and B.

### First Embodiment

Hereinafter, a semiconductor device according to the present embodiment and a method of manufacturing the semiconductor device are described. To simplify the description, details of semiconductor layers and electrodes may be omitted in each of the drawings.

### Configuration of Semiconductor Device

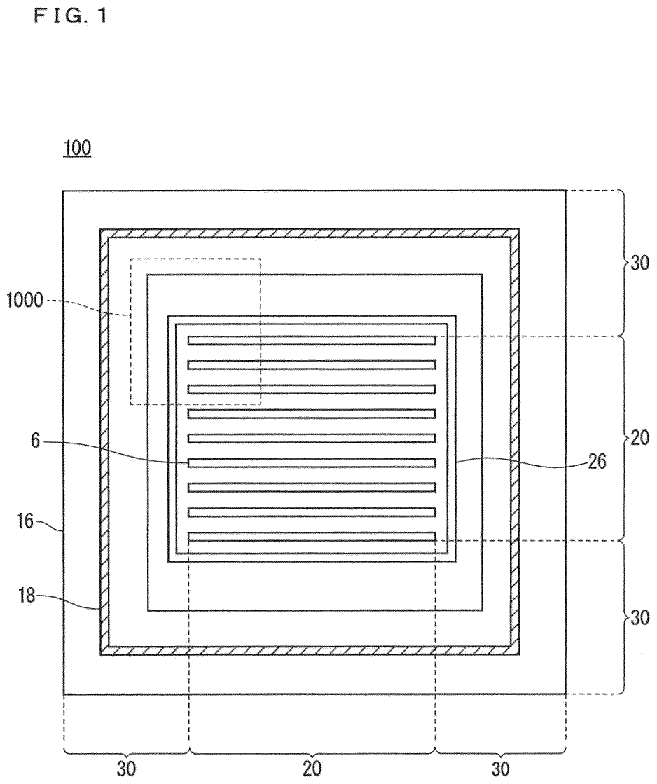

FIG. 1 is a plan view schematically showing an example of a configuration of a semiconductor device 100 according to the present embodiment. As shown in the example in FIG. 1, the semiconductor device 100 includes an active area 20 and a termination area 30.

The active area 20 includes a plurality of gate trenches 6 aligned in plan view. The termination area 30 includes a terminal trench 16 and a gate line 18 that is formed overlapping the terminal trench 16 in plan view. The termination area 30 further includes a gate trench 26 formed in an inner portion.

The active area 20 is provided in a central portion of the semiconductor device 100. The active area 20 is an area where current is passed through the semiconductor device 100 by the application of a voltage to the gate trenches 6 formed in stripes within the active area 20.

In the ON state of the semiconductor device 100, a positive volage is applied to the gate trenches 6 to evoke electrons at the interface between a gate insulating film and a semiconductor layer and to allow the passage of current.

The termination area 30 is formed around the active area 20 in plan view. The termination area 30 includes the terminal trench 16, a gate insulating film 17, gate electrodes 8, the gate line 18, and a guard ring given for the purpose of relieving an electric field. The terminal trench 16 is a trench provided in the termination area 30.

Although a first conductivity type is described as an n type and a second conductivity type as a p type in the present embodiment, the first conductivity type and the second conductivity type may also be a p type and an n type, respectively, in the semiconductor device.

While the semiconductor device is described as an MOSFET in the present embodiment, the semiconductor device may also be an IGBT. While the present embodiment describes a case in which a drift layer included in the semiconductor layer is formed of silicon carbide (SIC), the drift layer may also be a wide-bandgap semiconductor such as gallium nitride (GaN) or diamond that has a greater bandgap than silicon,

In FIG. 1, the semiconductor layer of the semiconductor device 100 includes the gate trenches 6 formed in the active area 20, and the gate trench 26 and the terminal trench 16 that are formed in the termination area 30. In plan view, the terminal trench 16 surrounds the gate trenches 6 and the gate trench 26 in plan view and is spaced from the gate trenches 6 and the gate trench 26.

As shown in the example in FIG. 1, the gate trenches 6 are formed in stripes in plan view. Each region partitioned by the gate trenches 6 in the active area 20 includes a plurality of cells (cell portion), and these cells function as MOSFETs.

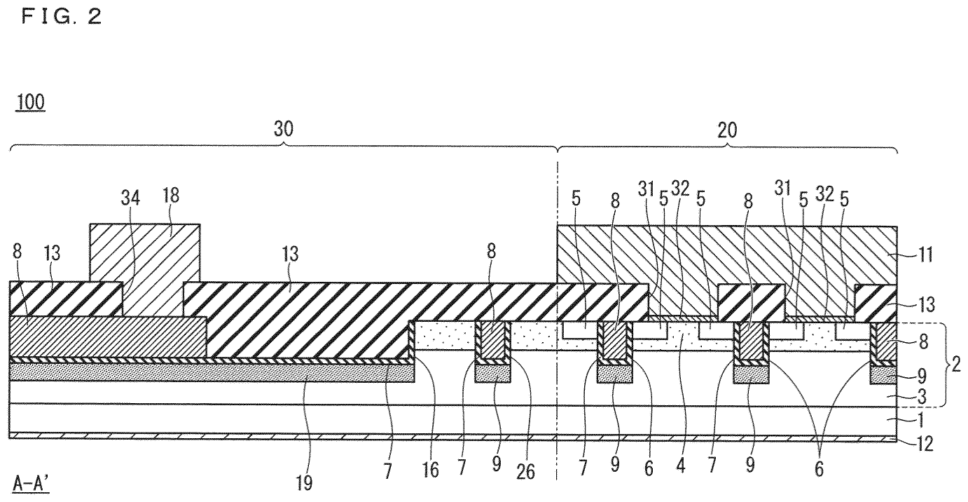

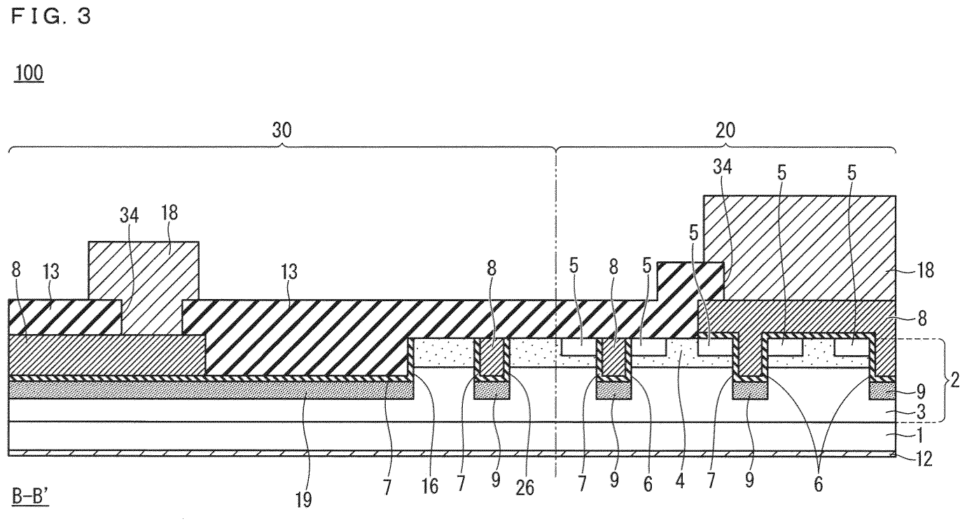

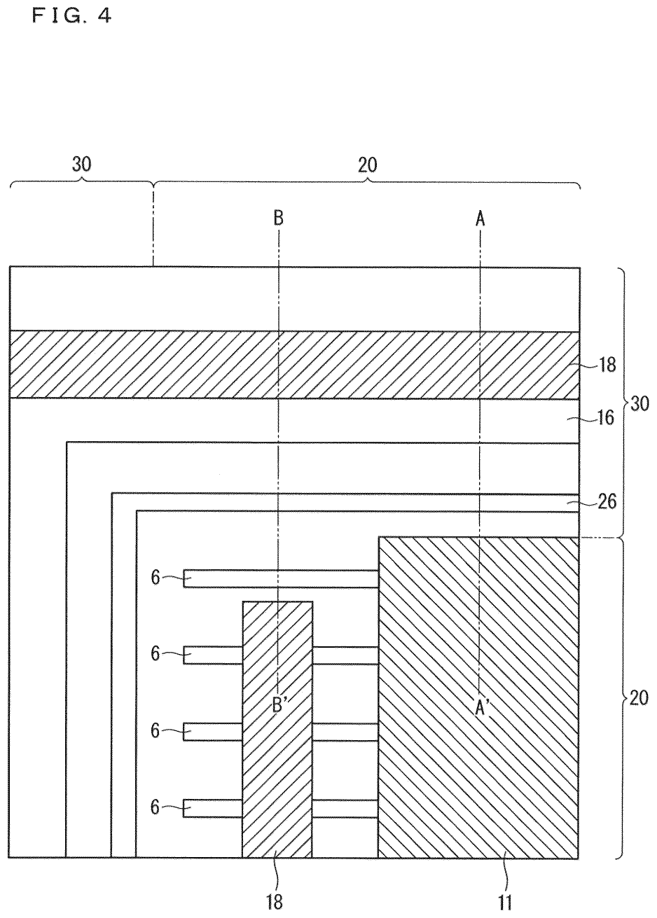

FIGS. 2 and 3 are sectional views showing part of the configuration of the semiconductor device according to the present embodiment. FIG. 4 is a plan view showing part of the configuration of the semiconductor device according to the present embodiment. The configurations shown in FIGS. 2, 3, and 4 correspond to a region 1000 enclosed by a broken line in FIG. 1. The section shown in FIG. 2 corresponds to a section A-A′ shown in FIG. 4. Similarly, the section shown in FIG. 3 corresponds to a section B-B′ shown in FIG. 4.

As shown in the examples in FIGS. 2 and 3, the semiconductor device 100 serving as an MOSFET includes an n-type silicon carbide semiconductor substrate 1 and a semiconductor layer 2 formed by epitaxial growth on the upper surface of the silicon carbide semiconductor substrate 1. The semiconductor device 100 further includes a drain electrode 12 formed on the lower surface of the silicon carbide semiconductor substrate 1.

The semiconductor layer 2 in the active area 20 includes a drift layer 3 formed of an n-type silicon carbide semiconductor, a p-type base region 4 provided in a surface layer of the drift layer 3, n-type source regions 5 selectively provided in a surface layer of the base region 4, the gate trenches 6 passing through the source regions 5 and the base region 4 and formed with their bottom faces located within the drift layer 3, and a p-type diffusion protective layer 9 provided under the bottom faces of the gate trenches 6.

Meanwhile, the semiconductor layer 2 in the termination area 30 includes the drift layer 3 formed of an n-type silicon carbide semiconductor, the p-type base region 4 provided in the surface layer of the drift layer 3, the gate trench 26 and the terminal trench 16 that are formed with their bottom faces located deeper than the base region 4 within the n-type drift layer 3, the p-type diffusion protective layer 9 provided under the bottom face of the gate trench 26, and a p-type terminal protective layer 19 provided under the bottom face of the terminal trench 16.

In the case where the semiconductor device 100 is an IGBT, the conductivity type of the silicon carbide semiconductor substrate 1 may be a p type.

Here, the drift layer 3 may have an n-type impurity concentration of, for example, higher than or equal to 1×10¹⁴ cm⁻³ and lower than or equal to 1×10¹⁷ cm⁻³ and may have a thickness of, for example, greater than or equal to 5 μm and less than or equal to 200 μm.

The base region 4 may have a p-type impurity concentration of, for example, higher than or equal to 1×10¹⁷ cm⁻³ and lower than or equal to 1×10²⁰ cm⁻³.

The source regions 5 may have an n-type impurity concentration of higher than or equal to the p-type impurity concentration of the base region 4 and lower than or equal to 1×10²¹ cm⁻³.

The diffusion protective layer 9 and the terminal protective layer 19 may have p-type impurity concentrations of, for example, higher than or equal to 1×10¹⁷ cm⁻³ and lower than or equal to 1×10¹⁹cm⁻³. Preferably, the p-type impurity concentration of the diffusion protective layer 9 may be the same as the p-type impurity concentration of the terminal protective layer 19, or may be higher than or equal to the p-type impurity concentration of the terminal protective layer 19.

As shown in the examples in FIGS. 2 and 3, the gate insulating film 7 is formed on the side and bottom faces of the gate trenches 6, and the gate electrodes 8 formed of polysilicon are embedded in the gate trenches 6 via the gate insulating film 7. However, in FIG. 3, the gate insulating film 7 and the gate electrodes 8 provided in the gate trenches 6 that overlap the gate line 18 in plan view are formed to extend to on the upper surface of the semiconductor layer 2 (the upper surface of the semiconductor layer 2 in which the base region 4 or the source regions 5 are formed).

Similarly, the gate insulating film 7 having the same thickness as the gate insulating film 7 formed in the gate trenches 6 is formed on the side and bottom faces of the gate trench 26, and the gate electrode 8 formed of polysilicon is embedded in the gate trench 26 via the gate insulating film 7. The gate electrode 8 provided in the gate trench 26 is formed to the upper surface of the semiconductor layer 2. The gate line 18 is provided across the upper surfaces of the gate electrodes 8 provided in the gate trenches 6.

The polysilicon formed to extend to the upper surface of the semiconductor layer 2 includes the gate electrodes 8 formed via contact holes (gate contacts 34). The gate electrodes 8 extend to a bonding pad for wire-bonding connection during assembly of a chip.

As shown in the examples in FIGS. 2, 3, and 4, the gate trench 26 that does not function electrically is formed in a boundary portion between the termination area 30 and the active area 20.

In the termination area 30, the terminal trench 16 is formed wider than the gate trenches 6 and the gate trench 26, and on the side and bottom faces of the terminal trench 16, the gate insulating film 7 is formed with the same thickness as the gate insulating film 7 formed in the gate trenches 6. Moreover, an interlayer insulation film 13 (oxide film) is deposited on part of the inside of the terminal trench 16, and the gate electrode 8 is formed on the other part of the inside of the terminal trench 16.

Gate electrodes 8 are also formed in the gate trenches 6 within the cell portion. Polysilicon (gate electrode 8) is also deposited in the gate trench 26 provided in the boundary portion between the termination area 30 and the active area 20.

The interlayer insulation film 13 is formed to cover the upper surface of the semiconductor layer 2 including the gate electrodes 8. Then, the gate line 18 is formed in contact with the gate electrodes 8 that are exposed through the gate contacts 34 serving as openings formed in the interlayer insulation film 13. The gate contacts 34 include those that expose the gate electrode 8 provided in the terminal trench 16 in the termination area 30 and those that expose the gate electrodes 8 extending from the gate trenches 6 to the upper surface of the semiconductor layer 2 in the active area 20. Moreover, a source electrode 11 is formed in contact with the upper surfaces of the base region 4 and the source regions 5 via an Ohmic electrode 32, the upper surfaces of the base region 4 and the source regions 5 being exposed through source contacts 31 serving as openings formed in the interlayer insulation film 13.

An oxide film (the interlayer insulation film 13) is formed in the terminal trench 16 in the termination area 30, whereas polysilicon is formed in the gate trenches 6 and the gate trench 26. That is, different materials are formed in the terminal trench 16 and the gate trenches 6 and 26.

Besides, the terminal trench 16 in the termination area 30 is processed in large dimensions, whereas the gate trenches 6 or the gate trench 26 in the cell portion is formed with a minimum processing linewidth. Due to this difference in structure, the expansion coefficients of materials vary depending on the thermal history in the wafer process. This produces residual stresses, and as a result a difference of electrical characteristics occurs between elements and affects the reliability of the semiconductor device.

In each cell arranged in the active area 20, stresses increase with approach toward the outer peripheral portions of the gate trenches. This effect increases the failure rate of the gate insulating film 7 with approach toward the outer peripheral portions of the gate trenches. Accordingly, failures of elements are suppressed by electrically isolating the outermost peripheral cells from the other cells and bringing the gate potential into a floating state.

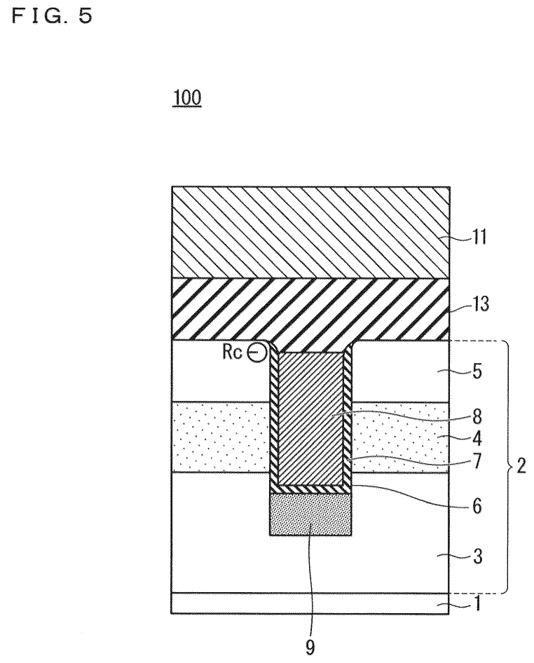

FIG. 5 is a sectional view showing an example of a configuration of the cell portion in FIG. 2. As shown in the example in FIG. 5, the upper corner portion of each gate trench 6 has a rounded shape.

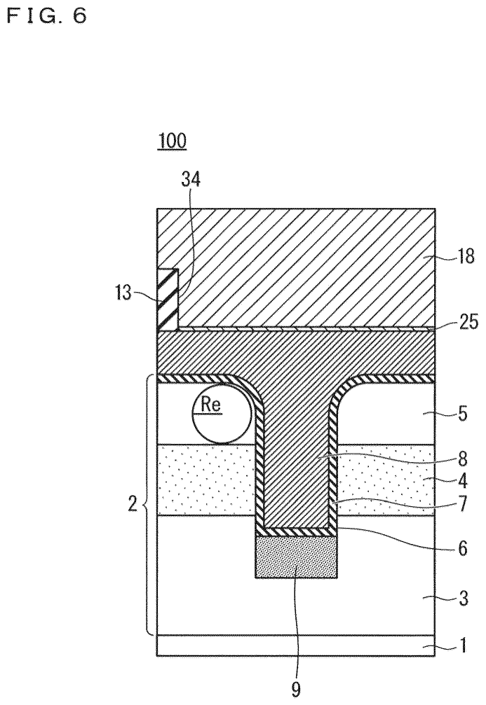

FIG. 6 is a sectional view showing an example of a configuration of a gate contact portion in the active area 20 shown in FIG. 3. As shown in the example in FIG. 6, the upper corner portion of each gate trench 6 has a rounded shape.

As shown in FIG. 5, the upper corner portion of the semiconductor layer 2 in the cell portion where the gate electrode 8 is embedded in the gate trench 6 has a shape whose roundness is indicated by a radius of curvature Rc. Thus, the gate insulating film 7 formed in this portion also has a shape with roundness indicated by the radius of curvature Rc.

As shown in FIG. 6, the upper corner portion of the semiconductor layer 2 in the gate contact portion that includes the gate electrode 8 extending from the gate trench 6 to on the upper surface of the semiconductor layer 2 has a shape with roundness indicated by a radius of curvature Re. Thus, the gate insulating film 7 formed in this portion also has a shape with roundness indicated by the radius of curvature Re.

A comparison of the radii of curvature of the gate trenches 6 provided immediately under the above-described gate insulating films 7 shows that Re>Rc, so the shape of the gate contact portion is gentler than the shape of the cell portion. The small radius of curvature Rc in the cell portion may, for example, be greater than 0 μm and less than or equal to 0.1 μm. The radius of curvature Re in the gate contact portion may, for example, be greater than or equal to 0.1 μm and less than or equal to 2 μm. In particular, excellent characteristics are provided if the radius of curvature Re in the gate contact portion is greater than or equal to 0.5 μm and less than or equal to 2 μm.

In the gate contact portion, the gate insulating film 7 and the gate electrode 8 are formed on the upper corners of the gate trenches 6. Since the radius of curvature Re is greater than the radius of curvature Rc, it is possible to suppress the application of a high electric field to the gate insulating film 7 formed on the upper corner portions of the gate trenches 6 in the ON-state of the MOSFET.

For example, in the case where the gate insulating film 7 has a thickness of 50 nm and a gate voltage of 20V is applied, an electric field of 4 MV/cm is applied to the side wall portions of the gate trenches 6. In this case, in the gate contact portion where the gate insulating film 7 is formed to have roundness with the radius of curvature Re, it is possible to suppress the application of a high electric field to the gate insulating film 7 formed on the upper corner portions of the gate trenches 6 and thereby to suppress the destruction of the insulating film.

From the viewpoint of the reliability of the gate insulating film 7, it is desirable to design the radius of curvature Re such that the increment of an electric field applied to the gate insulating film 7 in the vicinity of the gate trenches 6 with the radius of curvature Re is suppressed to 5% or less.

Although the gate contact portion shown in FIG. 6 is assumed to be provided in the active area 20, a configuration is also possible in which the upper corner portion of the terminal trench 16 has a rounded shape in the gate contact portion of the termination area 30 (the portion where the gate line 18 and the gate electrodes 8 are connected to each other via the gate contacts 34).

In the present embodiment, in the case where an Ohmic electrode is provided between the source electrode and the semiconductor layer, the source electrode and the Ohmic electrode may be collectively referred to as the source electrodes without distinction. Similarly, in the case where an Ohmic electrode is provided between the gate bonding pad serving as a metal electrode and the gate electrodes formed of a semiconductor or the like, the gate bonding pad and the Ohmic electrode may be collectively referred to as the gate bonding pads without distinction.

That is, the source electrode and the gate bonding pad according to the preset embodiment are not limited to being formed of unitary metal, and may include a material suitable for bonding to the semiconductor layer at the joint with the semiconductor layer. The Ohmic electrode is not limited to metal, and may be silicide or a compound of metal and a semiconductor. The Ohmic electrode may also include a plurality of metal layers or a conductor such as a semiconductor.

### Method of Manufacturing Semiconductor Device

Next, a method of manufacturing the semiconductor device 100 according to the present embodiment is described.

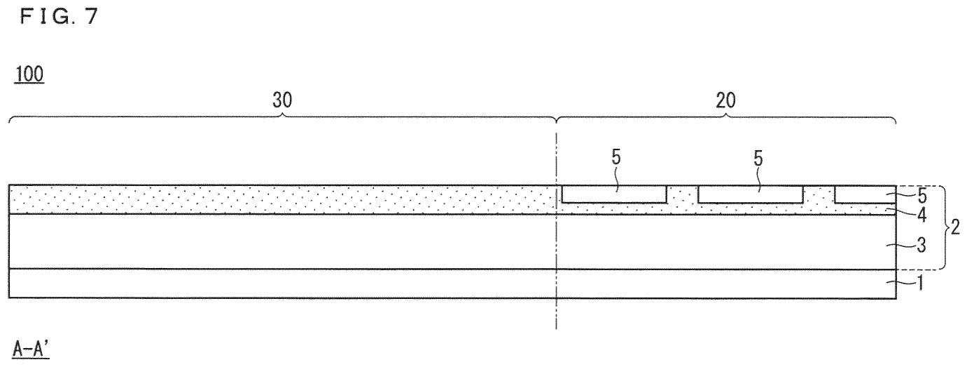

FIGS. 7 to 18 are diagrams showing an example of the method of manufacturing the semiconductor device according to the present embodiment.

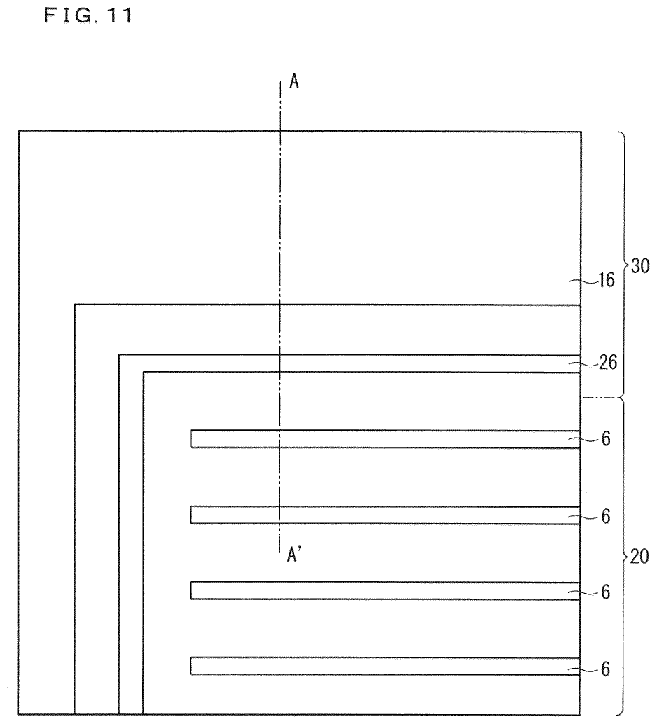

FIGS. 7 to 11 show an example of steps until the diffusion protective layer 9 is formed on the bottom faces of the gate trenches 6, and the terminal protective layer 19 is formed on the bottom face of the terminal trench 16. FIGS. 7 to 10 correspond to a section A-A′ shown in FIG. 11.

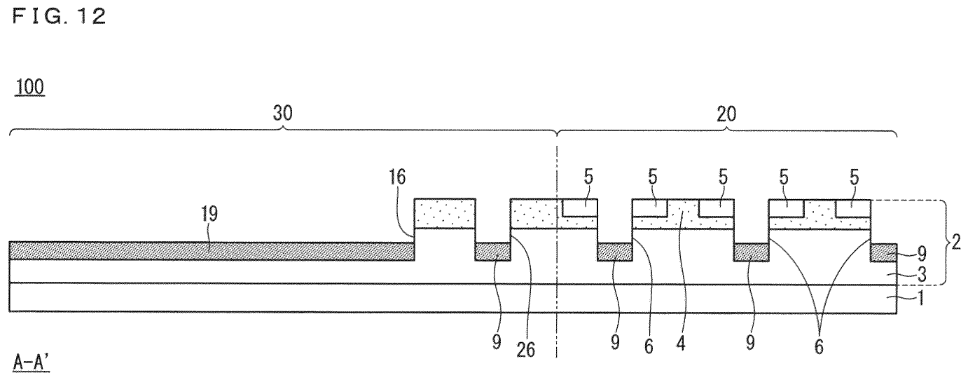

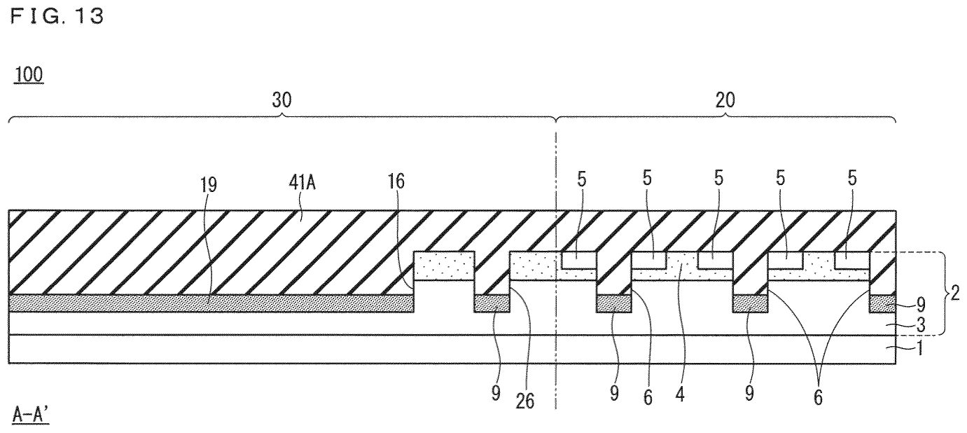

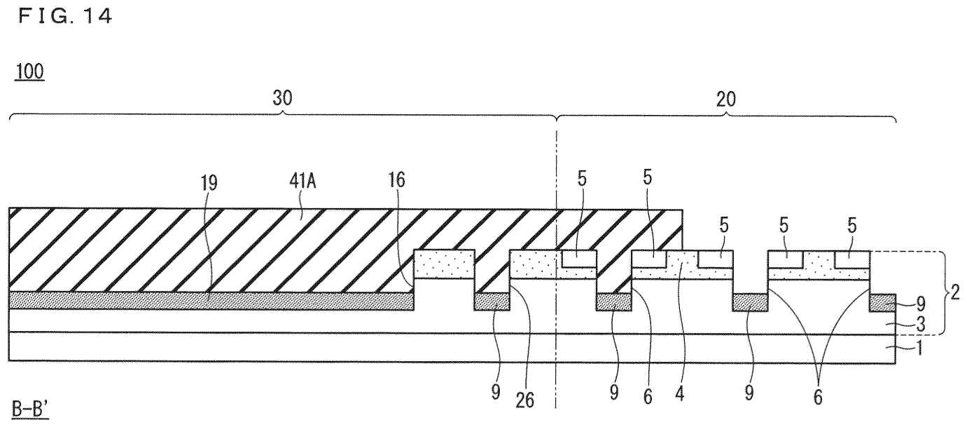

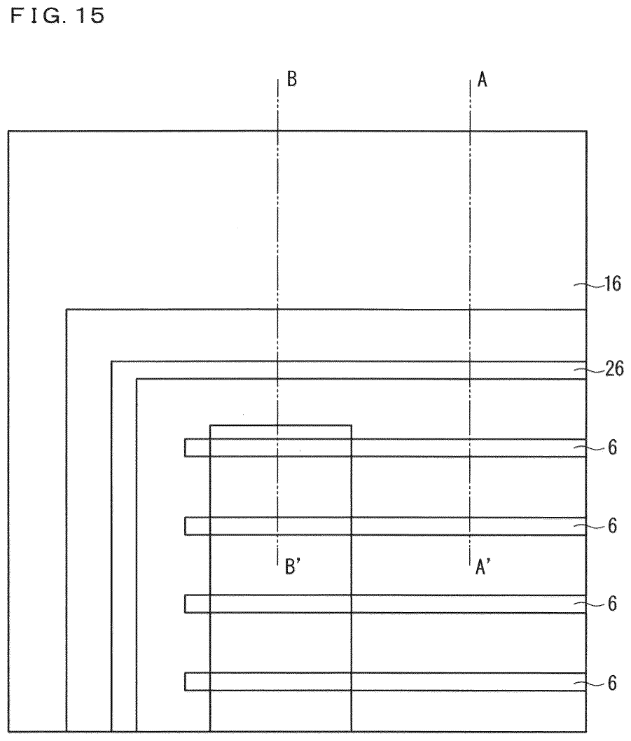

FIGS. 12 to 15 show an example of steps until the gate electrodes 8 are formed after the diffusion protective layer 9 and the terminal protective layer 19 have been formed. FIGS. 12 and 13 correspond to a section A-A′ shown in FIG. 15. FIG. 14 corresponds to a section B-B′ shown in FIG. 15.

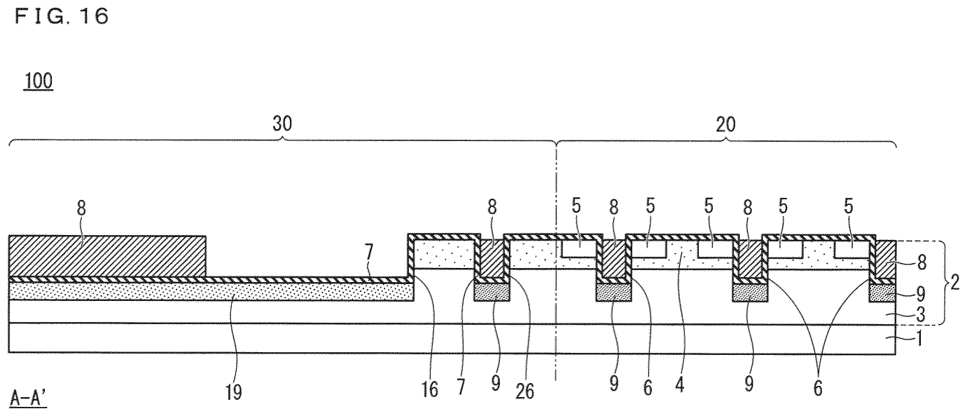

FIGS. 16 to 18 show an example of steps until the semiconductor device 100 is completed after the gate electrodes 8 have been formed.

First, as shown in the example in FIG. 7, the n-type silicon carbide semiconductor substrate 1 of a 4H polytype is prepared, and the n-type semiconductor layer 2 is epitaxially grown on the upper surface of the semiconductor substrate 1 by chemical vapor deposition (CVD).

At this time, the n-type semiconductor layer 2 may have an n-type impurity concentration of, for example, higher than or equal to 1×10¹⁴ cm⁻³ and lower than or equal to 1×10¹⁷ cm⁻³ and a thickness of, for example, greater than or equal to 5 μm and less than or equal to 200 μm.

Then, as shown in the example in FIG. 7, aluminum (Al) ions serving as a p-type impurity are implanted in the surface layer of the epitaxially grown semiconductor layer 2 so as to form the base region 4. The depth of Al ion implantation is set not to exceed the thickness of the semiconductor layer 2, and may be set in the range of, for example, greater than or equal to 0.3 μm and less than or equal to 3 μm. The impurity concentration of Al ions implanted is set to be higher than the n-type impurity concentration of the epitaxially grown semiconductor layer 2, and the p-type impurity concentration of the base region 4 may be set in the range of, for example, higher than or equal to 1×10¹⁷ cm⁻³ and lower than or equal to 1×10²⁰ cm⁻³. As a result, a region of the semiconductor layer 2 that is other than the base region 4 and located deeper than the depth of Al ion implantation forms the n-type drift layer 3.

Note that the base region 4 may be formed by epitaxially growing a p-type semiconductor, and in that case, the base region 4 may have the same p-type impurity concentration and thickness as the base region 4 formed by ion implantation.

Then, as shown in the example in FIG. 7, nitrogen (N) ions serving as an n-type impurity are selectively implanted in the surface layer of the base region 4 so as to form the source regions 5. The source regions 5 are formed into a pattern corresponding to the layout of the gate electrodes 8 to be formed in a subsequent step. The depth of N ion implantation is set to be less than the thickness of the base region 4. The impurity concentration of N ions implanted is set to be higher than or equal to the p-type impurity concentration of the base region 4 and lower than or equal to 1×10²¹ cm⁻³.

Note that the sequence of the step of implanting Al ions to form the base region 4 and the step of implanting N ions to form the source regions 5 may be changed. Alternatively, after an n-type semiconductor layer is formed by implanting N ions in the entire surface layer of the base region 4, portions that are to be left as the source regions 5 may be masked, and Al ions may be implanted again in non-masked regions (regions other than the source regions 5) so as to turn these non-masked regions back to the p-type base region 4. At this time, in order to reduce contact resistance with the source electrode, the impurity concentration of Al ions implanted again may be set to be higher than the impurity concentration of Al in the portion of the base region 4 that is located adjacent to the drift layer 3.

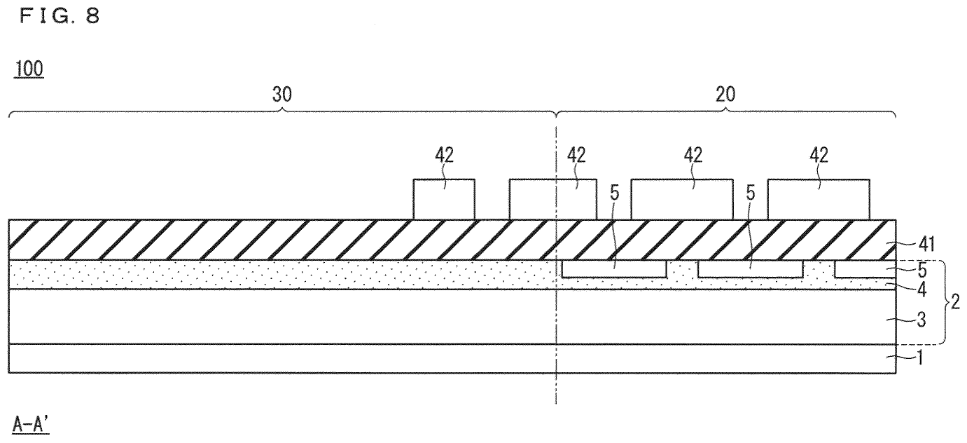

Then, as shown in the example in FIG. 8, a silicon oxide film 41 is formed on the upper surface of the semiconductor layer 2, and an etching mask 42 is further formed on the upper surface of the silicon oxide film 41. The silicon oxide film 41 may be formed by deposition to a thickness of, for example, greater than or equal to 1 μm and less than or equal to 2 μm, and thereafter the etching mask 42 is formed on the upper surface of the silicon oxide film 41. The etching mask 42 has a pattern formed by photolithography and having openings that correspond to regions where the gate trenches 6, the gate trench 26, and the terminal trench 16 are to be formed.

Then, the silicon oxide film 41 is patterned by reactive ion etching (RIE) using the etching mask 42 as a mask. That is, the pattern of the etching mask 42 is transferred to the silicon oxide film 41, and the silicon oxide film 41 is used as an etching mask for the semiconductor layer 2.

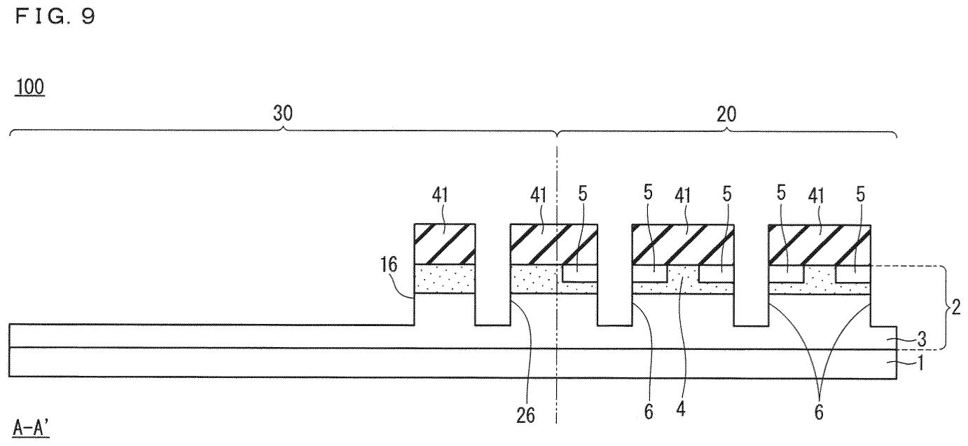

Then, as shown in the example in FIG. 9, the gate trenches 6 and the gate trench 26 that penetrate the source regions 5 and the base region 4 and the terminal trench 16 that penetrates the base region 4 are formed in the semiconductor layer 2 by RIE using the patterned silicon oxide film 41 as a mask.

The depths of the gate trenches 6, the gate trench 26, and the terminal trench 16 are greater than or equal to the depth of the base region 4 formed in the semiconductor layer 2 by ion implantation, and may be in the range of, for example, greater than or equal to 1.0 μm and less than or equal to 6.0 μm.

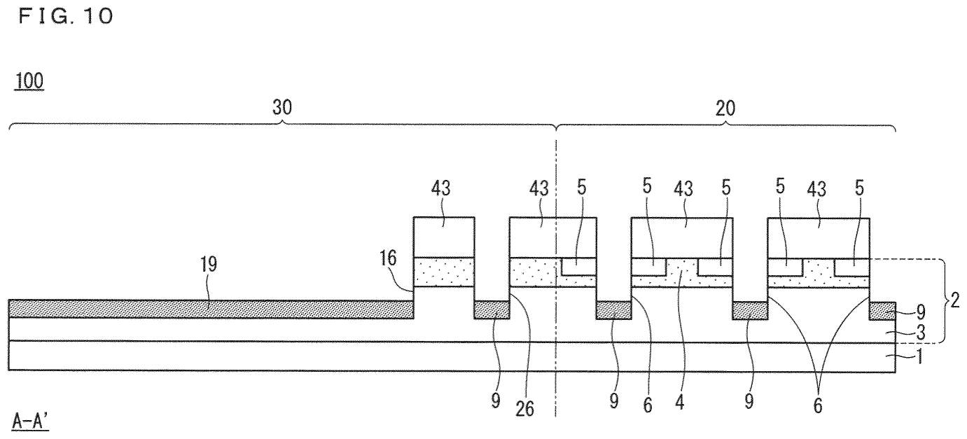

The gate trenches 6, the gate trench 26, and the terminal trench 16 are formed using the silicon oxide film 41 as a mask. Then, after the formation of the gate trenches 6, the gate trench 26, and the terminal trench 16, as shown in the example in FIG. 10, an implantation mask 43 having openings of the same pattern as that of the silicon oxide film 41 is formed, and the p-type diffusion protective layer 9 is formed by Al ion implantation at the bottoms of the gate trenches 6 and the gate trench 26. Similarly, the p-type terminal protective layer 19 is formed by Al ion implantation at the bottom of the terminal trench 16. Preferably, the impurity concentration of Al ions implanted may, for example, be higher than or equal to 1×10¹⁷ cm⁻³ and lower than or equal to 1×10¹⁹ cm⁻³, and the depth of ion implantation may, for example, be greater than or equal to 0.1 μm and less than or equal to 2.0 μm. The impurity concentration of Al ions implanted may be determined by an electric field that is applied to the gate insulating film 7 when the same voltage as the withstand voltage of the semiconductor device 100 is applied between the drain electrode 12 and the source electrode 11 of the semiconductor device 100.

If etching conditions and the thickness of the silicon oxide film 41 are controlled such that the silicon oxide film 41 remains even after used as a mask to form the gate trenches 6 and the terminal trenches 16, the remaining silicon oxide film 41 described above can be used as a mask, instead of the implantation mask 43, to form the diffusion protective layer 9 and the terminal protective layer 19. This simplifies the manufacturing process and reduces the manufacturing cost.

If Al ions are implanted in an oblique direction with respect to the openings of the gate trenches 6 in the case of forming the diffusion protective layer 9, it is possible to form a p-type semiconductor layer within the drift layer 3 that is in contact with the side faces of the gate trenches 6 and to use the p-type semiconductor layer to connect the p-type diffusion protective layer 9 and the p-type base region 4. This provides electrical connection between the diffusion protective layer 9 and the source electrode 11.

After the formation of the diffusion protective layer 9 and the terminal protective layer 19, the implantation mask 43 used for ion implantation is removed, and annealing processing for activating the implanted impurities is performed using a heat treatment apparatus. The annealing processing may be performed by heating impurities at a temperature of higher than or equal to 1300° C. and lower than or equal to 1900° C. for 30 seconds or more and one hour or less in a vacuum or in an inert gas atmosphere such as an argon (Ar) atmosphere.

Then, as shown in the example in FIG. 12, the implantation mask 43 is removed and the upper surface of the semiconductor layer 2 is oxidized in the section A-A′ and the section B-B′ shown in FIG. 15. The oxide film formed on the upper surface of the semiconductor layer 2 may have a thickness on the order of, for example, greater than or equal to 5 nm and less than or equal to 100 nm. Thereafter, the oxide film is removed by hydrofluoric acid-based wet etching. Through this step, the upper corner portion of each trench is rounded (with the radius of curvature Rc).

Then, an oxide film 41A is deposited as shown in the example in FIG. 13, and only portions of the oxide film 41A that correspond to regions where the gate contacts are to be formed in the active area 20 are opened as shown in the example in FIG. 14.

Then, as shown in the example in FIG. 14, in the section B-B′ shown in FIG. 15, the oxide film 41A is etched so as to expose part of the semiconductor layer 2, and the upper corner portions of the gate trenches 6 in the exposed semiconductor layer 2 are rounded (with the radius of curvature Re). The section B-B′ in FIG. 15 shows that a range that spans a plurality of gate trenches 6 is exposed from the oxide film 41A.

The rounded shape may be formed by chemical dry etching (CDE: isotropic etching) or by any other etching processing (e.g., heat treatment in a hydrogen atmosphere). Thereafter, the oxide film 41A is removed.

In the area where the upper corner portions of the trenches are rounded (with the radius of curvature Rc) by the step shown in FIG. 12, the upper corner portions of the gate trenches 6 are further rounded with a larger radius of curvature as a result of CDE or heat treatment conducted in a hydrogen atmosphere in the step shown in FIG. 14.

As described above, the radius of curvature Re of the gate insulating film 7 provided on the upper corner portions of the gate trenches 6 (or the terminal trench 16) in the area where the gate line 18 is provided on the upper surface is greater than the radius of curvature Rc of the gate insulating film 7 provided on the upper corner portions of the gate trenches 6 in the area where the source electrodes 11 are electrically connected to the adjacent source regions 5. With this configuration, even if a gate voltage is applied to the gate insulating film 7 of a rounded shape with a great radius of curvature (the radius of curvature Re), the concentration of an electric field is effectively suppressed due to the great radius of curvature, and the application of a high electric field is suppressed. Accordingly, it is possible to suppress the destruction of the gate insulating film 7.

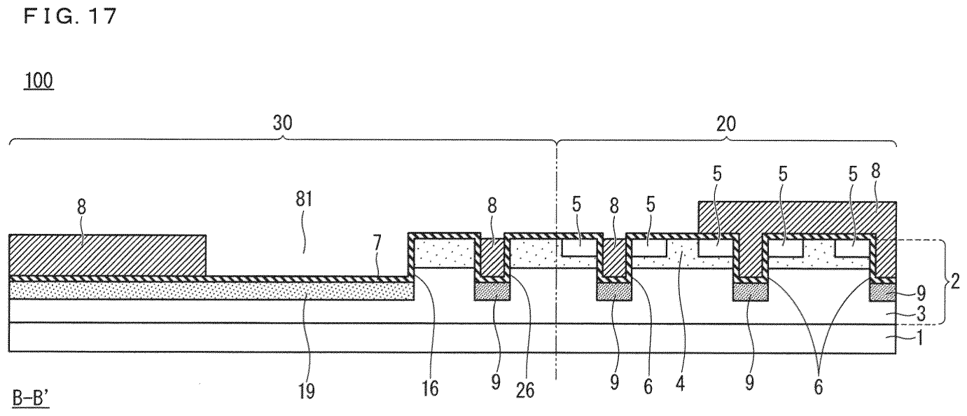

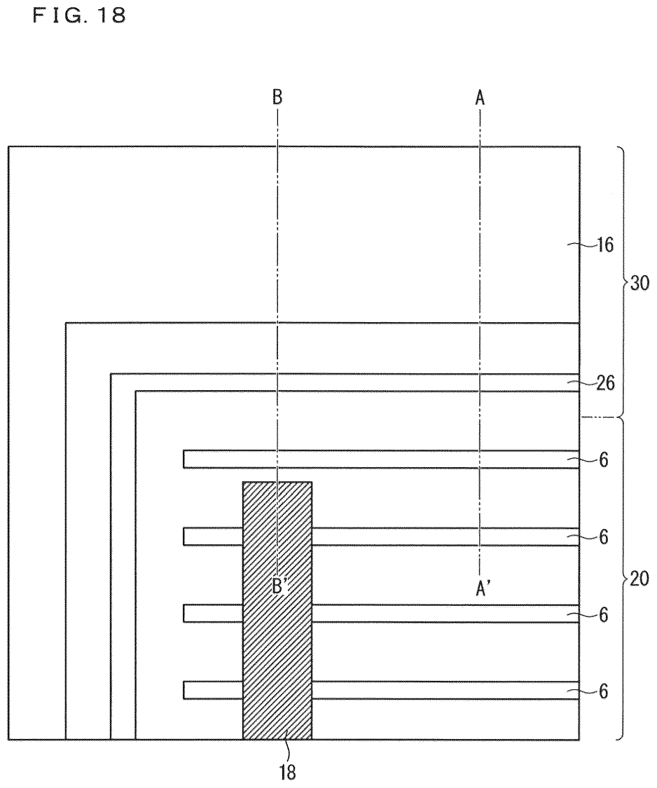

Next, the gate electrode 8 is formed. FIG. 16 corresponds to a section A-A′ shown in FIG. 18. FIG. 17 corresponds to a section B-B′ shown in FIG. 18.

As shown in the example in FIG. 16, the gate insulating film 7 and the gate electrode 8 are formed in the gate trenches 6, the gate trench 26, and the terminal trench 16. Specifically, polysilicon that forms the gate electrodes 8 is deposited after deposition of the gate insulation film 7. Thereafter, the deposited polysilicon is etched back using a resist as a mask. Accordingly, the polysilicon in a region with no resist is etched back, whereas the polysilicon remains in the gate trenches 6, the gate trench 26, and the terminal trench 16.

Meanwhile, as shown in the example in FIG. 17, the regions covered with the aforementioned resist are regions where the upper corner portions of the gate trenches 6 are rounded (with the radius of curvature Re), and the polysilicon remains also on a mesa region (the upper surface of the semiconductor layer 2) without being etched back. Since the upper corner portions of the gate trenches 6 are greatly rounded (with the radius of curvature Re), there is no need to locally increase the thickness of the gate insulating film 7 in order to suppress the concentration of an electric filed on the upper corner portions of the gate trenches 6. Accordingly, it is possible, by one process of forming the gate insulating film, to manufacture the structure capable of suppressing the concentration of an electric field on the upper corner portions of the gate trenches 6 and to suppress an increase in manufacturing cost without increasing the number of manufacturing steps.

Then, the interlayer insulation film 13 is formed to cover the gate electrodes 8 by low-pressure CVD on the upper surface of the semiconductor layer 2. Then, the interlayer insulation film 13 is patterned to form contact holes (gate contacts 34) that reach the source regions 5 and the base region 4 in the active area 20 and the termination area 30. Moreover, contact holes (source contacts 31) that reach the gate electrodes 8 are formed in the active area. Thereafter, an Ohmic electrode 25 is formed in the gate contacts 34 (see FIG. 6). The Ohmic electrode 32 is also formed in the source contacts 31. Each of the Ohmic electrodes may be a silicide film formed by first depositing a metal film composed primarily of nickel (Ni) on the upper surface of the semiconductor layer 2 or on the upper surfaces of the gate electrodes 8 and then causing Ni to react with a semiconductor by heat treatment conducted at a temperature of, for example, higher than or equal to 600° C. and lower than or equal to 1100° C.

Thereafter, an Al alloy or the like is deposited on the upper surface of the interlayer insulation film 13 and in the gate contacts 34 and the source contacts 31, and patterned to form the gate line 18 via the gate contacts 34 and to form the source electrode 11 via the source contacts 31.

Then, the drain electrode 12 is formed by depositing an Al alloy or the like on the surface of the silicon carbide semiconductor substrate 1 on the side opposite to the side where the semiconductor layer 2 is formed. Through the steps described above, the semiconductor device 100 is formed.

### Functions and Effects of Semiconductor Device

Next, functions and effects of the semiconductor device 100 according to the present embodiment are described.

The semiconductor device 100 according to the present embodiment shown in FIGS. 2 to 5 controls a channel to be formed in the base region 4 that opposes the gate electrodes 8 via the gate insulating film 7, and controls ON-and OFF-states of the semiconductor device 100 by controlling a voltage applied between the gate electrodes 8 and the source electrodes 11.

When a voltage that is high enough to turn on the semiconductor device 100 is applied between the gate electrodes 8 and the source electrode 11, a voltage higher than or equal to a threshold value is applied to the gate electrodes 8. As a result, a channel is formed in the base region 4 that opposes the gate electrodes 8 via the gate insulating film 7, and a path for passing electrons serving as carriers is formed between the n-type source regions 5 and the n-type drift layer 3.

Then, the electrons flowing from the source regions 5 into the drift layer 3 is caused to reach the drain electrode 12 via the drift layer 3 and the silicon carbide semiconductor substrate 1 by an electric field created by the voltage applied between the drain electrode 12 and the source electrode 11. As a result, current flows from the drain electrode 12 to the source electrode 11 with the application of a voltage higher than or equal to the threshold value to the gate electrodes 8. This state corresponds to the ON-state of the semiconductor device 100.

On the other hand, when a voltage that is lower than the threshold value is applied between the gate electrodes 8 and the source electrode 11, no channel is formed in the base region 4 that opposes the gate electrodes 8 via the gate insulating film 7. In this case, the presence of the p-type base region 4 between the n-type source regions 5 and the n-type drift layer 3 prevents the passage of current from the drain electrode 12 to the source electrode 11. This state corresponds to the OFF-state of the semiconductor device 100.

When the semiconductor device 100 is turned off, a high voltage supplied from an external electric circuit is applied between the drain electrode 12 and the source electrode 11. In the OFF state of the semiconductor device 100, a depletion layer grows from the diffusion protective layer 9 and the terminal protective layer 19 into the drift layer 3. This inhibits the electric field created by the voltage applied between the drain electrode 12 and the source electrode 11 from concentrating on the gate insulating film 7 at the bottoms of the gate trenches 6, and suppresses the destruction of the gate insulating film 7 at the bottoms of the gate trenches 6 even if a high electric field is applied to the gate insulating film 7.

On the other hand, when the semiconductor device 100 is turned on, a voltage supplied from an external electric circuit is applied between the gate electrodes 8 and the source electrode 11. As a result of the application of the voltage, an electric field is applied to the gate insulating film 7. Since the upper corner portions of the gate trenches 6 in the semiconductor layer 2 have a rounded shape with the radius of curvature Re, the gate insulating film 7 also has a rounded shape with the radius of curvature Re. This inhibits the electric field created by the voltage applied between the drain electrode 12 and the source electrode 11 from concentrating on the gate insulating film 7 on the upper corner portions of the gate trenches 6, and suppresses the destruction of the gate insulating film 7 even if an electric field is applied to the gate insulating film 7.

When the semiconductor device 100 is turned on, current flows from the drain electrode 12 toward the source electrode 11 with a voltage supplied from an external electric circuit. Thus, the voltage between the drain electrode 12 and the source electrode 11 becomes an ON-state voltage that is determined by the on-state resistance of the semiconductor device 100 and the current flowing from the drain electrode 12 toward the source electrode 11. The ON-state voltage is much lower than the voltage applied between the drain electrode 12 and the source electrode 11 in the OFF-state. Therefore, the depletion layer that has expanded in the OFF-state from the diffusion protective layer 9 and the terminal protective layer 19 into the drift layer 3 in the OFF-state shrinks toward the diffusion protective layer 9 and the terminal protective layer 19 in the ON-state.

That is, when the semiconductor device 100 repeatedly switches between the ON-state and the OFF-state, the depletion layer that expands from the diffusion protective layer 9 and the terminal protective layer 19 to the drift layer 3 grows and shrinks in accordance with the switching.

Although the semiconductor device 100 functions while switching repeatedly between the ON-state and the OFF-state, voltage stresses are imposed on the gate insulating film 7 and accelerates deterioration even during the repeated switching between the ON-state and the OFF-state. Since the upper corner portions of the gate trenches 6 in the semiconductor layer 2 have a rounded shape with the radius of curvature Re, the gate insulating film 7 provided on this portion also has a rounded shape with the radius of curvature Re. This prevents the electric field applied between the drain electrode 12 and the source electrode 11 from concentrating on the gate insulating film 7 formed on the upper corner portion of the semiconductor layer 2. Accordingly, it is possible to suppress acceleration of deterioration of the gate insulating film 7 and thereby to suppress the destruction of the gate insulating film 7.

In the present embodiment, as shown in FIG. 4, the gate trench 26 that does not function electrically is provided in the boundary portion between the termination area 30 and the active area 20. The termination area 30 and the active area 20 are different in their laminated structure and their processing dimensions in the direction along the silicon carbide semiconductor substrate 1. This may produce residual stresses in the aforementioned boundary portion, exert an influence on electrical characteristics, and become a cause of the destruction of the gate insulating film 7. The gate insulating film 7 also has a higher failure rate with approach toward the outermost peripheral portion. Therefore, the destruction of elements can be suppressed by electrically isolating the outermost peripheral cells (corresponding to the gate trench 26) from the other cells as the termination area 30 and bringing the gate potential into a floating state without electrically connecting the gate electrodes 8 to the source electrode 11 and the gate line 18.

The gate trenches 26 shown in FIG. 4 will have a higher efficiency percentage when increased in number. That is, the quality of the semiconductor device 100 is improved by forming a plurality of gate trenches 26.

### Second Embodiment

A semiconductor device according to the present embodiment and a method of manufacturing the semiconductor device are described. In the following description, constituent elements that are identical to those described in the above embodiment are given the same reference signs, and detailed description thereof shall be omitted as appropriate.

### Configuration of Semiconductor Device

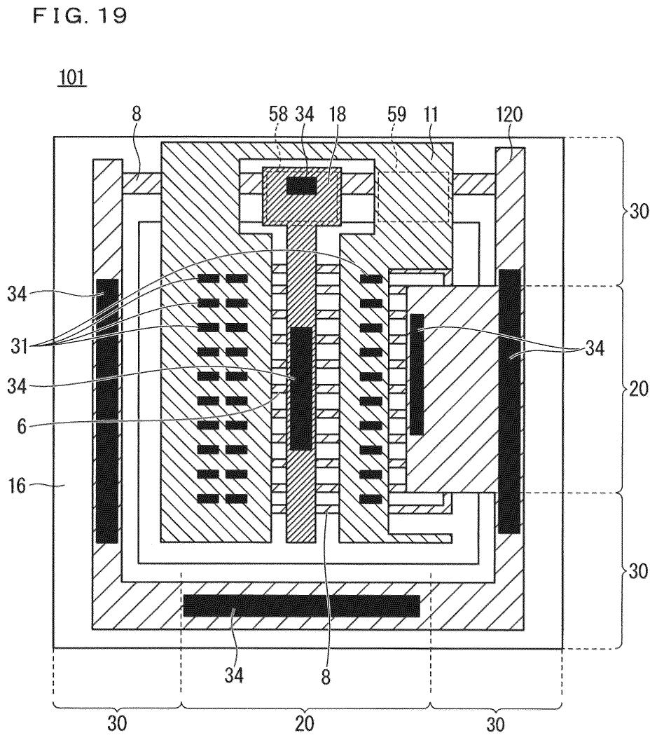

FIG. 19 is a plan view schematically showing an example of a configuration of a semiconductor device 101 according to the present embodiment. As shown in the example in FIG. 19, the semiconductor device 101 includes an active area 20 and a termination area 30.

The active area 20 includes a plurality of gate trenches 6 aligned in plan view, gate electrodes 8 formed in the gate trenches 6, and a gate line 18 connected to the gate electrodes 8 via gate contacts 34. The gate contacts 34 are formed immediately under the gate line 18 and immediately above the gate electrodes 8.

The gate electrodes 8 are connected to a gate bonding pad 58 arranged in the outer peripheral portion of a chip. The gate bonding pad 58 and the gate electrodes 8 are metal layers such as aluminum and are formed by the same process.

A source electrode 11 is formed on the upper surface of source regions 5 formed in the surface layer of a semiconductor layer 2. The source electrode 11 is electrically connected to the source regions 5 via contact holes (source contacts 31). The source electrode 11 extends to a source bonding pad 59.

The termination area 30 includes a terminal trench 16 and a gate line 18 arranged in some regions within the terminal trench 16. A metal line 120 is formed on the upper surface of the gate line 18 via a gate contact 34. The metal line 120 is formed by the same process as the gate electrodes 8 and the source electrode 11. Since the metal line 120 and the gate line 18 are connected in parallel, electric resistance becomes low. The semiconductor device 101 is configured as described above.

### Method of Manufacturing Semiconductor Device

Next, a method of manufacturing the semiconductor device 101 according to the present embodiment is described.

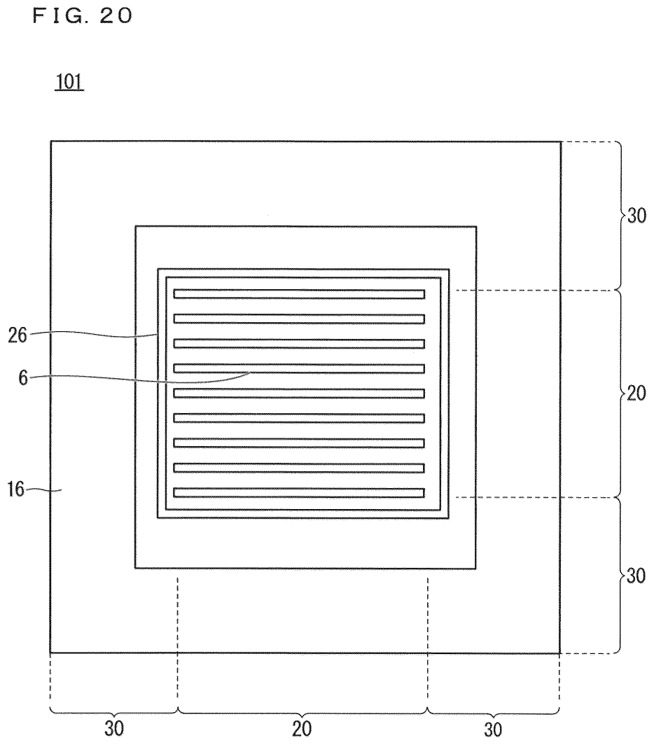

FIGS. 20 to 22 are diagrams showing an example of the method of manufacturing the semiconductor device according to the present embodiment.

The structure shown in FIG. 20 corresponds to a plan view of the structure shown in FIG. 10. The gate trenches 6 are formed in the active area 20, and the outermost gate trench 26 and the terminal trench 16 are formed in the termination area 30.

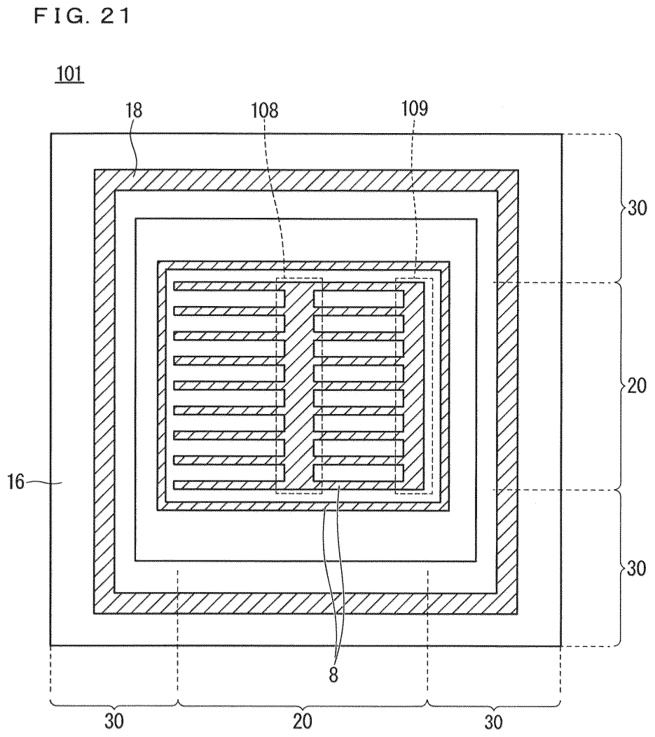

The structure shown in FIG. 21 corresponds to a plan view of the structure shown in FIG. 16 in plan view. The gate line 18 is formed on the gate trenches 6 in the active area 20. The gate line 18 is also formed on the gate trench 26 in the termination area 30. The gate line 18 is further formed on some regions of the terminal trench 16.

The gate line 18 is formed by depositing polysilicon on the gate trenches 6 and etching back the polysilicon with use of a mask formed of a resist or the like on some regions.

Regions 108 and 109 indicated by broken lines in FIG. 21 are regions where the aforementioned mask is provided so that the polysilicon also remains on the upper surface of the semiconductor layer 2 without being etched back. The polysilicon remaining in these regions covers not only the insides of the gate trenches 6 but also the upper corner portions of the gate trenches 6, and also remains on the mesa region (the upper surface of the semiconductor layer 2). The upper corner portions of the gate trenches 6 have a great radius of curvature Re and suppress the concentration of an electric field. Accordingly, it is possible to suppress the destruction of the gate insulating film 7.

In FIG. 21, the gate electrode 8 formed in the gate trench 26 in the termination area 30 is isolated in plan view from the gate electrodes 8 formed in the gate trenches 6 arranged in stripes in the central portion of the active area 20. As shown in FIGS. 16 to 18, the gate line 18 is formed by etching back the deposited polysilicon.

In the etchback process, polysilicon remains in a sidewall shape on the side wall portions of trenches in the area where there is a trench level difference (area where the upper surface is at different levels due to the presence of the trenches). In such a structure that includes the remaining polysilicon having electrical connection, an electric field is also applied to the gate insulating film 7 on the underside of the polysilicon remaining in a sidewall shape, and the destruction of the gate insulating film 7 occurs. In contrast, in the structure shown in FIG. 21, the potential of the polysilicon remining in a sidewall shape is floating, and no electrical connection is established with the gate electrodes. Accordingly, it is possible to suppress the destruction of the gate insulating film 7.

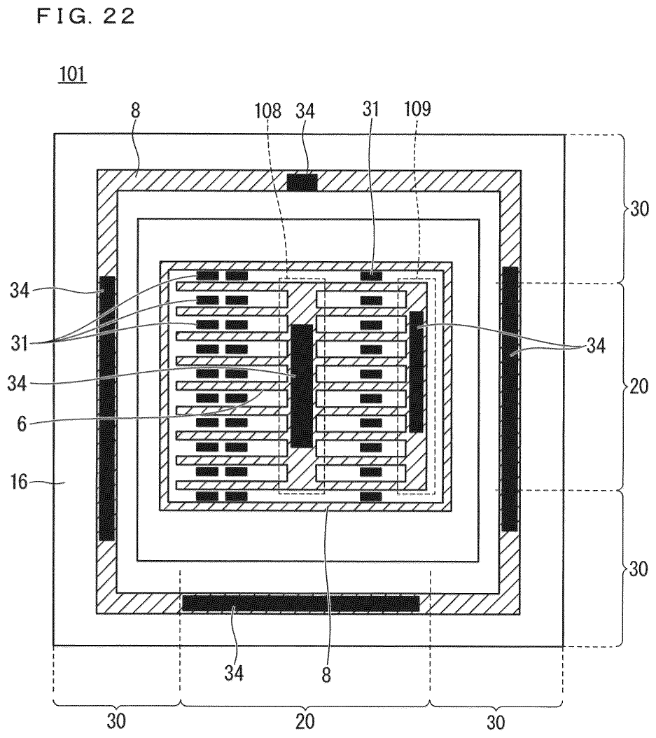

FIG. 22 is a plan view showing an example of the structure when firstly the interlayer insulation film 13 and then the source contacts 31 and the gate contacts 34 are formed after the step shown in FIG. 21.

In FIG. 22, the gate contacts 34 are formed on the upper surfaces of the gate electrodes 8 in the regions 108 and 109. In the structure shown in FIG. 22, the gate contacts 34 and the gate line 18 can be formed at positions overlapping the gate trenches 6 arranged in stripes in plan view. Thus, there is no need to separately provide a region for forming the gate contacts 34. This reduces chip area and increases the degree of flexibility in design layout.

Thereafter, as shown in FIG. 19, aluminum is deposited and patterned by etching using a resist mask. Then, in the region 108, the gate line 18 is formed and connected to the gate bonding pad 58. In the regions 109, the aluminum is patterned to form the metal line 120, and the metal line 120 extends to the upper surface of the gate electrode 8 formed in the termination area 30. Then, the metal line 120 is electrically connected to the gate electrodes 8 via the contact holes (the gate contacts 34). The gate electrodes 8 in the termination area 30 extend to immediately under the gate bonding pad 58 and are electrically connected to the gate electrodes 8 via the gate contacts 34 within the gate bonding pad 58.

The gate electrodes 8 provided in the gate trenches 6 in a cell array are electrically connected to each other via the gate contacts 34 provided in the gate bonding pad 58 and in the central portion of the active area 20, and are also electrically connected to the gate electrodes 8 and the aluminum layer (the metal line 120) formed in the termination area 30 and to the other gate electrodes 8 in the active area 20. This lowers the resistance value of the gate electrodes 8 in the gate trenches 6 provided in the active area 20 and achieves excellent electrical characteristics (switching characteristics and ON-state characteristics).

The upper corner portions of the gate trenches 6 in the region 108, which is located in the central portion of the active area 20 where the gate contact 34 is formed, are formed with a great radius of curvature Re. Thus, it is possible to suppress the concentration of an electric field on the upper corner portions of the gate trenches 6 even with the application of a gate voltage during element operations, and thereby to suppress the destruction of the gate insulating film 7.

### Third Embodiment

A semiconductor device according to the present embodiment and a method of manufacturing the semiconductor device are described. In the following description, constituent elements that are identical to those described in the above embodiments are given the same reference signs, and detailed description thereof shall be omitted as appropriate.

### Configuration of Semiconductor Device

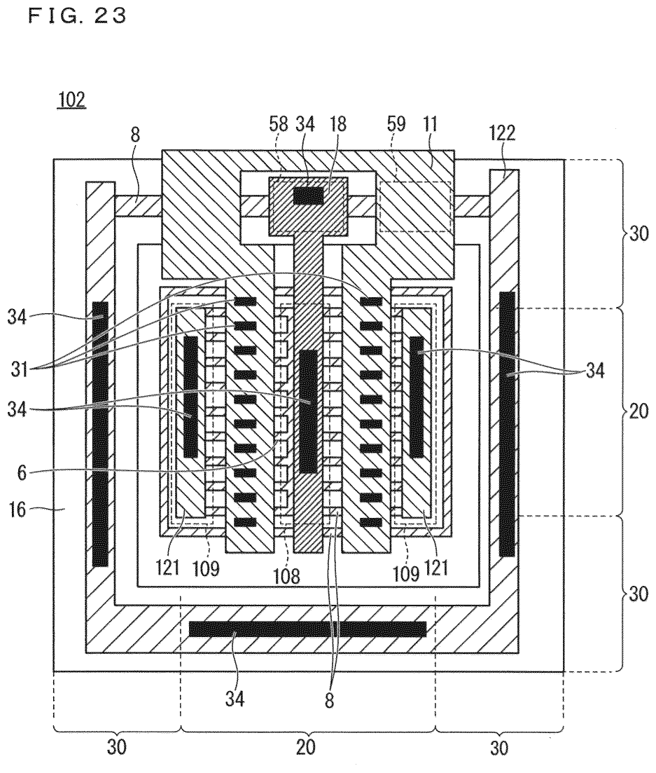

FIG. 23 is a plan view schematically showing an example of a configuration of a semiconductor device 102 according to the present embodiment. As shown in the example in FIG. 23, the semiconductor device 102 includes an active area 20 and a termination area 30.

The active area 20 includes a plurality of gate trenches 6 aligned in plan view, gate electrodes 8 formed in the gate trenches 6, and a gate line 18 connected to the gate electrodes 8 via gate contacts 34. The gate contacts 34 are formed immediately under the gate line 18 and in the upper layers of the gate electrodes 8.

The gate electrodes 8 are connected to the gate bonding pad 58 arranged in the outer peripheral portion of a chip. The gate bonding pad 58 and the gate line 18 are metal layers of aluminum or the like and are formed by the same process.

A source electrode 11 is formed on the upper surfaces of source regions 5 formed in the surface layer of the semiconductor layer 2. The source electrode 11 is electrically connected to the source regions 5 via contact holes (source contacts 31). The source electrode 11 extends to the source bonding pad 59.

The termination area 30 includes a terminal trench 16 and gate electrodes 8 formed in some regions of the terminal trench 16. A metal line 122 is formed on the upper surfaces of the gate electrodes 8 via gate contacts 34. The metal line 122 is formed by the same process as the gate line 18 and the source electrode 11. Since the metal line 122 and the gate electrodes 8 are connected in parallel, gate resistance becomes low. The semiconductor device 102 is configured as described above.

### Method of Manufacturing Semiconductor Device

Next, a method of manufacturing the semiconductor device 102 according to the present embodiment is described.

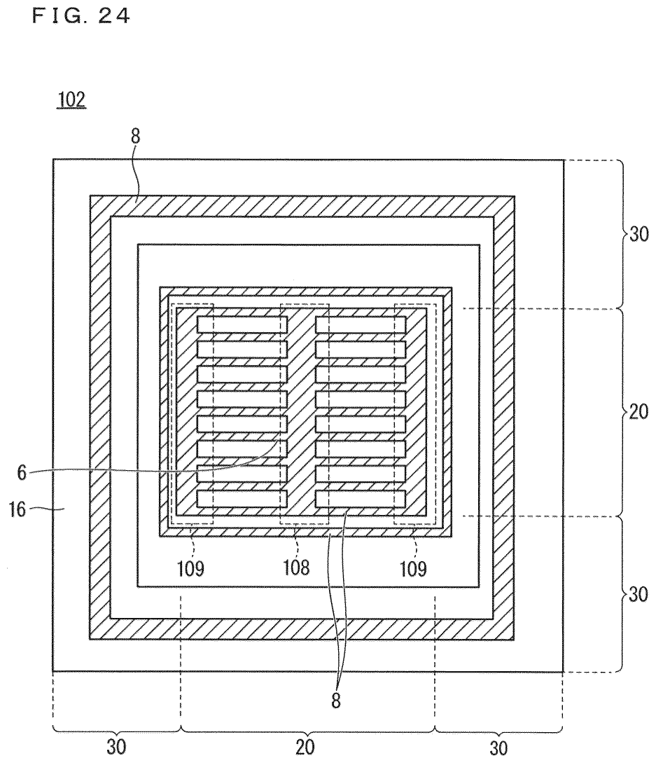

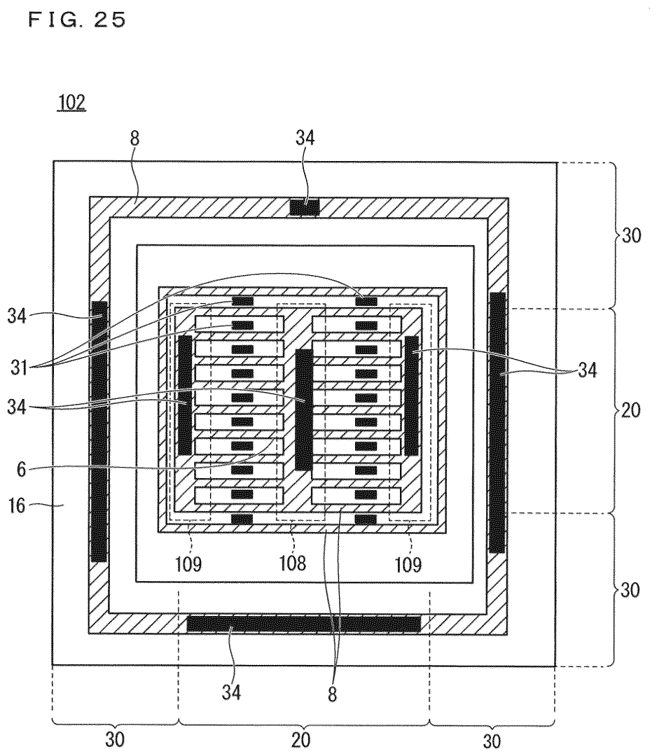

FIGS. 24 and 25 are diagrams showing an example of the method of manufacturing the semiconductor device according to the present embodiment.

The structure shown in FIG. 24 corresponds to a plan view of the structure shown in FIG. 16. The gate electrodes 8 are formed in the gate trenches 6 in the active area 20. The gate electrode 8 is also formed in the gate trench 26 in the termination area 30. The gate electrodes 8 are also formed in some regions of the terminal trench 16.

The gate electrodes 8 are formed by depositing polysilicon in the gate trenches 6 and then etching back the polysilicon with use of a mask formed of a resist or the like in some regions.

Regions 108 and 109 indicated by broken lines in FIG. 24 are regions in which the polysilicon remains on the upper surface of the semiconductor layer 2 without being etched back due to the presence of the aforementioned mask. The polysilicon remaining in these regions covers not only the insides of the gate trenches 6 but also the upper corner portions of the gate trenches 6 and also remains on the mesa region (the upper surface of the semiconductor layer 2). The upper corner portions of the gate trenches 6 have a great radius of curvature Re and prevent the concentration of an electric field. This suppresses the destruction of the gate insulating film 7.

Outermost peripheral end portions of the active area 20 (portions corresponding to the regions 109) shown in FIG. 24 provide electrical connection between the gate electrodes 8 aligned in stripes via the gate contacts 34. Thus, it is possible to lower the gate resistance of the gate trenches 6 formed narrow and long.

FIG. 25 is a plan view showing an example of the structure when firstly the interlayer insulation film 13 and then the source contact 31 and the gate contact 34 are formed after the step shown in FIG. 24.

In FIG. 25, the gate contacts 34 are formed on the upper surfaces of the gate electrodes 8 in the regions 108 and 109.

Thereafter, as shown in FIG. 23, aluminum is deposited and patterned by etching using a resist mask. Then, in the region 108, the gate electrodes 8 are formed and connected to the gate bonding pad 58 via the gate line 18. In the regions 109, the aluminum is patterned to form the metal line 122 (the gate line 18), and the metal line 122 extends to the upper surfaces of the gate electrodes 8 formed in the termination area 30. The metal line 122 is electrically connected to the gate electrodes 8 via the contact holes (the gate contacts 34). The gate line 18 in the termination area 30 extends to immediately under the gate bonding pad 58 and is electrically connected to the gate electrodes 8 via the gate contacts 34 within the gate bonding pad 58.

The gate electrodes 8 provided in the gate trenches 6 in a cell array are electrically connected to each other via the gate contacts 34 provided in the gate bonding pad 58 and in the central portion of the active area 20. The gate electrodes 8 provided in the gate trenches 6 in the cell array are also electrically connected to the other gate line 18 in the active area 20 via the aluminum layer (the electrode portion 121) and the gate contacts 34 formed in the end portion of the active area 20. This lowers the resistance value of the gate line 18 in the gate trenches 6 in the active area 20 and provides excellent electrical characteristics (switching characteristics and on-state characteristics).

The upper corner portions of the gate trenches 6 in the region 108, which is located in the central portion of the active area 20 where the gate contact 34 is formed, and the upper corner portions of the gate trenches 6 in the regions 109, which are located in the end portions of the active area 20, are both formed with a great radius of curvature Re. Thus, it is possible to suppress the concentration of an electric field on the upper corner portions of the gate trenches 6 even with the application of a gate voltage during clement operations and thereby to suppress the destruction of the gate insulating film 7.

### Fourth Embodiment

A semiconductor device according to the present embodiment and a method of manufacturing the semiconductor device are described. In the following description, constituent elements that are identical to those described in the above embodiments are given the same reference signs, and detailed description thereof shall be omitted as appropriate.

### Configuration of Semiconductor Device

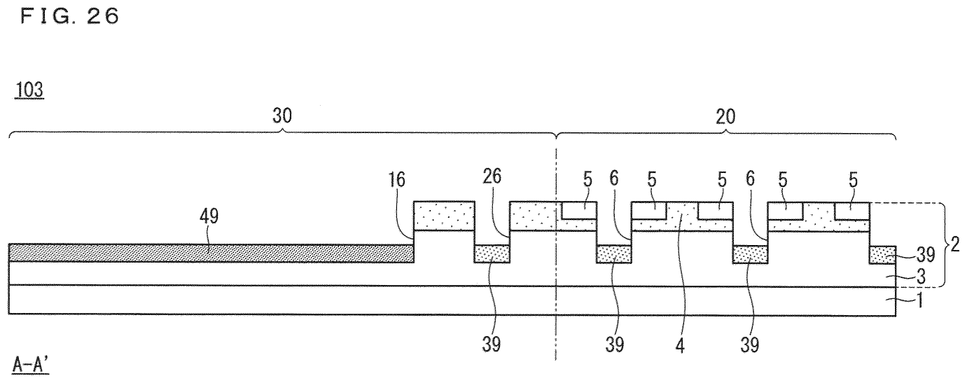

FIGS. 26 to 30 are sectional views schematically showing an example of a semiconductor device 103 according to the present embodiment. As shown in the example in FIGS. 26 to 30, the semiconductor device 103 includes an active area 20 and a termination area 30.

The active area 20 includes a plurality of gate trenches 6 aligned in plan view, gate electrodes 8 formed in the gate trenches 6, and a gate line 18 connected to the gate electrodes 8 via gate contacts 34. The gate contacts 34 are formed immediately under the gate line 18 and on the upper layers of the gate electrodes 8.

The gate electrodes 8 are connected to a gate bonding pad 58 arranged in the outer peripheral portion of a chip. The gate bonding pad 58 and the gate line 18 are metal layers of aluminum or the like and formed by the same process.

A source electrode 11 is formed on the upper surfaces of source regions 5 formed in the surface layer of a semiconductor layer 2. The source electrode 11 is electrically connected to the source regions 5 via contact holes (source contacts 31). The source electrode 11 extends to the source bonding pad 59.

The termination area 30 includes a terminal trench 16 and gate electrodes 8 formed in some regions of the terminal trench 16. A metal line 122 is formed on the upper surfaces of the gate electrodes 8 via gate contacts 34. The metal line 122 is formed by the same process as the gate electrodes 8 and the source electrode 11. Since the metal line 122 and the gate electrodes 8 are connected in parallel, gate resistance becomes low. The semiconductor device 103 is configured as described above.

### Method of Manufacturing Semiconductor Device

Next, the method of manufacturing the semiconductor device 103 according to the present embodiment is described.

The structure shown in FIG. 26 corresponds to a structure in a stage after completion of the steps from FIGS. 7 to 9.

As shown in the example in FIG. 26, after the formation of the gate trenches 6, the gate trench 26, and the terminal trench 16, impurities are implanted into the bottom faces of these trenches. Specifically, Al ions are implanted into the bottoms of the gate trenches 6 and the gate trench 26 to form a p-type diffusion protective layer 39. Similarly, Al ions are implanted into the bottom of the terminal trench 16 to form a p-type terminal protective layer 49. The impurity concentration of Al ions implanted may, for example, be higher than or equal to 1×10¹⁶ cm⁻³ and lower than or equal to 1×10¹⁸cm³, and the depth of ion implantation may, for example, be greater than or equal to 0.1 μm and less than or equal to 2.0 μm.

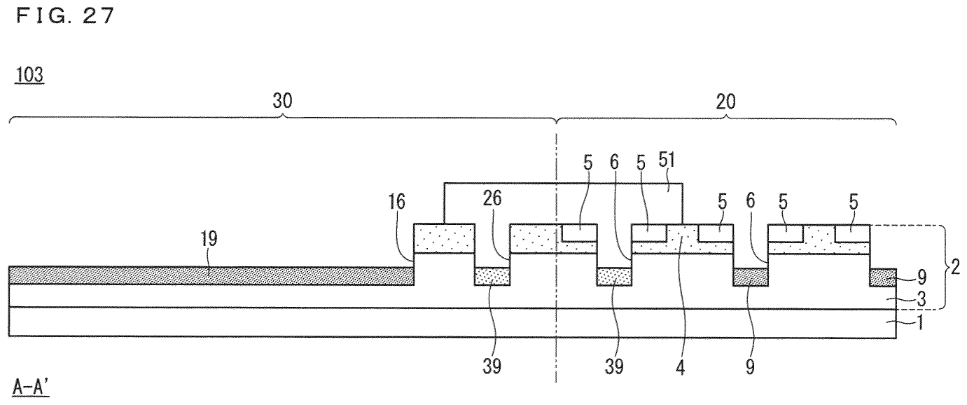

Thereafter, as shown in the example in FIG. 27, a resist mask 51 is formed on the gate trench 26 and gate trenches 6 that are located in the boundary portion between the active area 20 and the termination area 30. Then, Al ions are additionally implanted into exposed portions of the p-type diffusion protective layer 39 and the terminal protective layer 49. It is preferable that the impurity concentration of Al may, for example, be higher than or equal to 1×10¹⁶ cm⁻³ and lower than or equal too 1×10¹⁸ cm⁻³, and the depth of ion implantation may, for example, be greater than or qual to 0.1 μm and less than or equal to 2.0 μm.

As a result of the above two times of ion implantation, the diffusion protective layer 39 provided in the gate trench 26 and the gate trenches 6 located in the boundary portion between the active area 20 and the termination area 30 has a lower impurity concentration than the diffusion protective layer 9 provided in gate trenches 6 that have undergone the two times of ion implantation (the trenches formed in portions other than the boundary portion). Similarly, the diffusion protective layer 39 has a lower impurity concentration than the terminal protective layer 19 provided in the terminal trench 16 that has undergone the two times of ion implantation.

Thereafter, the resist is removed, and annealing processing for activating impurities implanted by ion implantation is further performed by a heat treatment apparatus. The annealing processing may be performed by heating at a temperature of, for example, higher than or equal to 1300° C. and lower than or equal to 1900° C. for 30 minutes more or one hour or less in a vacuum or in an inert gas atmosphere such as an argon (Ar) atmosphere.

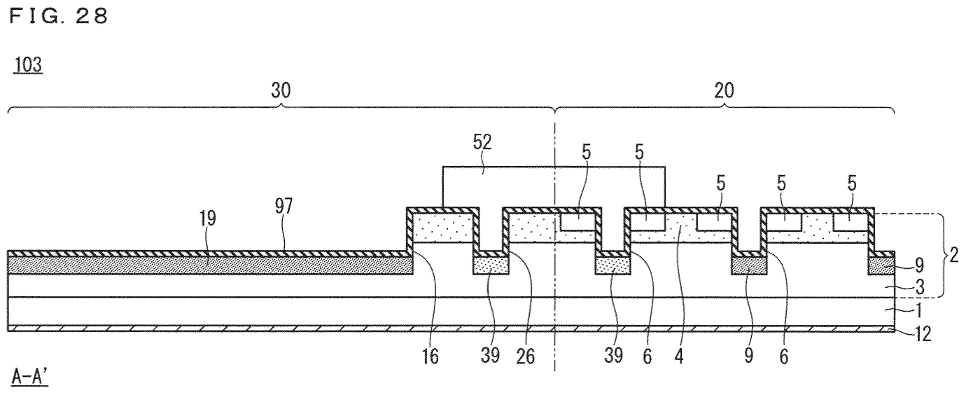

Then, a gate insulating film 97 is deposited as shown in the example in FIG. 28. Then, a resist mask 52 is formed on the gate trench 26 and the gate trenches 6 located in the boundary portion between the active area 20 and the termination area 30, and the gate insulating film 97 provided in regions that are not covered by the resist mask 52 is removed by wet processing using, for example, a hydrofluoric acid. Here, the gate insulating film 97 may have a film thickness of, for example, greater than or equal to 20 nm and less than or equal to 150 nm.

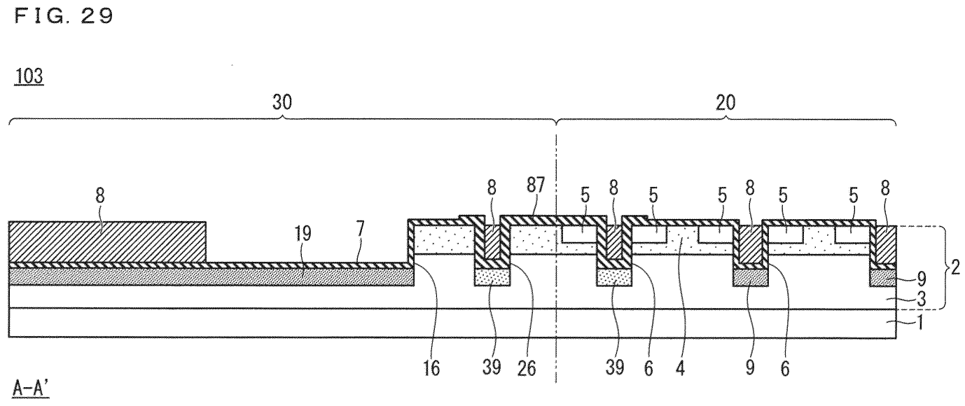

Thereafter, a gate insulating film is further deposited on the entire surface as shown in the example in FIG. 29. The hate insulating film further formed by the second deposition may have a thickness of, for example, greater than or equal to 20 nm and less than or equal to 150 nm.

As a result of the above two times of the deposition process, the gate insulating film 87 in some regions becomes thickener than the gate insulating film 7 in the other regions.

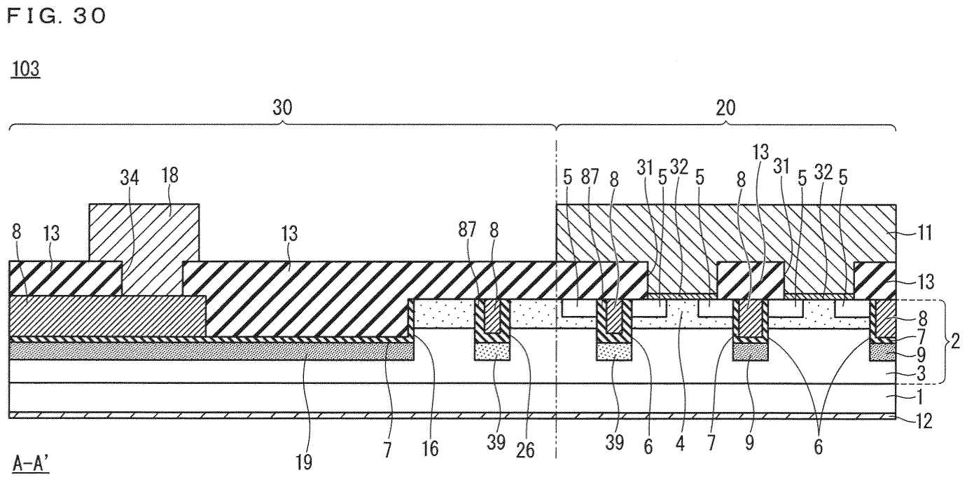

Thereafter, polysilicon that forms the gate electrodes 8 is deposited. Thereafter, the deposited polysilicon is etched back using a resist as a mask. From this point on, an interlayer insulation film 13, source contacts 31, gate contacts 34, an Ohmic electrode 32, a source electrode 11, and gate lines 18 are formed by the same process as described in the first embodiment so as to complete the MOSFET (see FIG. 30).

In the regions of the active area 20 where the gate contacts 34 are formed, polysilicon also remains on the mesa region (the upper surface of the semiconductor layer 2), and this region has a rounded shape with a great radius of curvature (the radius of curvature Re). Therefore, as in the case described in the first embodiment, it is possible to suppress the concentration of an electric field on the upper corner portions of the gate trenches 6 and thereby to suppress the destruction of the gate insulating film 7.

In the configuration shown in FIG. 30, the terminal trench 16 provided in the termination area 30 is processed in large dimensions, whereas the gate trenches 6 provided in the cell portion or the gate trench 26 are formed with a minimum processing line width. Due to this difference, the expansion coefficient depending on material varies in accordance with the thermal history in the wafer process. This produces residual stresses, results in a difference in electrical characteristics of elements, and exerts an influence on the reliability of the semiconductor device.

The cells arranged in the active area 20 also suffer higher stress with approach toward the outermost peripheral portions of the gate trenches. Due to this influence, the failure rate of the gate insulating film 7 becomes higher with approach toward the outermost peripheral portions of the gate trenches.

Thus, it is effective to bring the gate potential into a floating state by electrically isolating the outermost peripheral cells from the other cells, but this prevents the above region from functioning as an MOSFET.

In view of this, in the present embodiment, the gate insulating film 87 provided in the cells located in the peripheral portion (the boundary portion between the active area 20 and the termination area 30) is increased in thickness, or the impurity concentration of the diffusion protective layer 39 on these cells is designed to become lower than the impurity concentration of the diffusion protective layer 9 on the other cells in the active area 20. This suppresses the concentration of an electric field applied to the gate insulating film 87 when the semiconductor device is turned on by the application of a gate electrode. As a result, it is possible to suppress the destruction of the gate insulating film and to improve the reliability of the semiconductor device.

### Effects Produced by Above-Described Embodiments

The following shows examples of the effects produced by the above-described embodiments. Note that although the following description discusses these effects based on specific configurations whose examples are described in the above embodiments, the specific configurations may be replaced by any other specific configuration shown as an example in the specification of the present application within the range that similar effects are produced. That is, although, for the sake of convenience, only any one of associable specific configurations may be described below on behalf of all specific configurations, this specific configuration may be replaced by any other specific configuration associable with the specific configuration.

This replacement may be made across a plurality of embodiments. That is, similar effects may be produced by a combination of examples described in different embodiments.

According to the embodiments described above, the semiconductor device includes the drift layer 3 of the first conductivity type (the n type), the base region 4 of the second conductivity type (the p type) provided in the surface layer of the drift layer 3, the plurality of n-type source regions 5 provided in the surface layer of the base region 4, at least one trench (e.g., the gate trench 6, the gate trench 26, or the terminal trench 16) extending from the upper surface of the drift layer 3 to the inside of the drift layer 3 via the base region 4, the p-type protective layer (e.g., the diffusion protective layer 9, the diffusion protective layer 39, or the terminal protective layer 19) provided in the drift layer 3 under the trench, the gate insulating film 7 provided along the inside of the trench including the upper corner portion of the trench, and the gate electrodes 8 provided at least in the trench and surrounded by the gate insulating film 7. Here, the regions partitioned in the trench in plan view are defined as the first and second regions. The semiconductor device further includes the source electrode 11 electrically connected to the source regions 5 located adjacent to the trench in the first region (the gate trench 6), and the gate line 18 provided on the upper surface of the gate electrode 8 provided in the trench in the second region (the gate trench 6 or the terminal trench 16). The radius of curvature Re of the gate insulating film 7 provided on the upper corner portion of the trench in the second region (the gate trench 6 or the terminal trench 16) is greater than the radius of curvature Rc of the gate insulating film 7 provided on the upper corner portion of the trench in the first region (the gate trench 6).

With this configuration, even if a gate voltage is applied to the gate insulating film 7 formed in a rounded shape with a great radius of curvature (the radius of curvature Re), the concentration of an electric field is effectively suppressed due to the great radius of curvature, and the application of a high electric field is suppressed. Accordingly, it is possible to suppress the destruction of the gate insulating film 7.

Note that similar effects may also be produced even in the case where any other configuration that has been described as an example in the specification of the present application is appropriately added to the above-described configuration, i.e., even in the case where any other configuration that is not referred to as the above-described configuration but has been described in the specification of the present application is appropriately added to the above-described configuration.

According to the embodiments described above, the gate line 18 is provided on the upper surfaces of the gate electrodes 8 extending to the upper surfaces of the source regions 5. This configuration suppresses the destruction of the gate insulating film and improves the reliability of the semiconductor device.

According to the embodiments described above, the gate line 18 is connected via the plurality of contact holes (the gate contacts 34) to the upper surfaces of the gate electrodes 8 extending to the upper surfaces of the source regions 5. This configuration suppresses the destruction of the gate insulating film and improves the reliability of the semiconductor device.

According to the embodiments described above, the gate insulating film 7 provided in the trenches in the first region and the gate insulating film 7 provided in the trenches in the second region have an equal thickness. With this configuration, it is possible to form the gate insulating film 7 in a plurality of trenches by one process.

According to the embodiments described above, a plurality of trenches are provided. Then, at least one gate trench 6 is provided in the active area 20, and at least one gate trench 26 is provided in the termination area 30. The gate electrode 8 provided in the gate trench 26 in the termination area 30 is not electrically connected to the source electrode 11 and the gate line 18. With this configuration, the destruction of an element is suppressed by bringing the potential of the gate electrode 8 in the gate trench 26 into a floating state.

According to the embodiments described above, a plurality of trenches are provided. The gate trenches 6 are aligned in stripes in plan view. The gate line 18 is provided across the upper surfaces of the gate electrodes 8 provided in the gate trenches 6. This configuration suppresses the destruction of the gate insulating film and improves the reliability of the semiconductor device.

According to the embodiments described above, a plurality of trenches are provided. Then, at least one gate trench 6 is provided in the active area 20, and at least one terminal trench 16 is provided in the termination area 30. The terminal trench 16 provided in the termination area 30 is formed wider than the gate trenches 6 (or the gate trench 26) provided in the active area 20. This configuration creates a structure in which polysilicon does not remain on the side wall of the terminal trench 16. Accordingly, it is possible to suppress the destruction of the gate insulating film as compared to a structure in which an electric field is applied to the gate insulating film 7 serving as a lower layer via polysilicon that remains on the side wall of the terminal trench.

According to the embodiments described above, a plurality of trenches are provided. Then, at least one gate trench 6 is provided in the active area 20 surrounded by the termination area 30 in plan view. The gate insulating film 87 provided in the trenches in the boundary portion between the active area 20 and the termination area 30 (the gate trenches 6 and the gate trench 26) has a greater thickness than the gate insulating film 7 provided in the trenches in the active area 20 and the termination area 30 other than the boundary portion (the gate trenches 6 and the terminal trench 16). This configuration suppresses the concentration of an electric field applied to the gate insulating film 87 when the semiconductor device is turned on by the application of a gate voltage. As a result, it is possible to suppress the destruction of the gate insulating film and to improve the reliability of the semiconductor device.

According to the embodiments described above, a plurality of trenches are provided. Then, at least one gate trench 6 is provided in the active area 20 surrounded by the termination area 30 in plan view. The protective layer provided under the gate trenches 6 and the gate trench 26 in the boundary portion between the active area 20 and the termination area 30 (the diffusion protective layer 39) has a lower impurity concentration than the protective layer provided under the trenches (the gate trenches 6 and the terminal trench 16) in the active area 20 and the termination area 30 other than the boundary portion (the diffusion protective layer 9 or the terminal protective layer 19). This configuration suppresses the concentration of an electric field applied to the gate insulating film 87 when the semiconductor device is turned on by the application of a gate voltage. As a result, it is possible to suppress the destruction of the gate insulating film and to improve the reliability of the semiconductor device.

According to the embodiments described above, in the method of manufacturing the semiconductor device, the p-type base region 4 is provided in the surface layer of the n-type drift layer 3. Then, the plurality of n-type source regions 5 are provided in the surface layer of the base region 4. Then, at least one trench extending from the upper surface of the drift layer 3 to the inside of the drift layer 3 via the base region 4 (e.g., the gate trench 6, the gate trench 26, or the terminal trench 16) is provided. Then, the p-type protective layer (e.g., the diffusion protective layer 9, the diffusion protective layer 39, or the terminal protective layer 19) is provided in the drift layer 3 under the trench. Here, the regions partitioned in the trench in plan view are defined as the first and second regions, In the first and second regions, the upper corner portion of the trench (the gate trench 6) is etched. In the second region, the upper corner portion of the trench (the gate trench 6 or the terminal trench 16) is etched. Then, the gate insulating film 7 is provided along the inside of the trench including the upper corner portion of the trench. Then, the gate electrode 8 is provided in the trench surrounded by the gate insulating film 7. Then, the source electrode 11 is provided so as to be electrically connected to the source regions 5 located adjacent to the trench in the first region (the gate trench 6). Then, the gate line 18 is provided on the upper surface of the gate electrode 8 provided in the trench in the second region (the gate trench 6 or the terminal trench 16). Here, the radius of curvature Re of the gate insulating film 7 provided on the upper corner portion of the trench in the second region (the gate trench 6 or the terminal trench 16) is greater than the radius of curvature Rc of the gate insulating film 7 provided on the upper corner portion of the trench in the first region (the gate trench 6).

With this configuration, even if a gate voltage is applied to the gate insulating film 7 formed in a rounded shape with a great radius of curvature (the radius of curvature Re), it is possible to efficiently suppress the concentration of an electric field due to the great radius of curvature and to suppress the application of a high electric field. Accordingly, the destruction of the gate insulating film 7 is suppressed.

Note that the sequence of each processing may be changed, unless otherwise limited specifically.

Note that similar effects may also be produced even in the case where any other configuration that has been described as an example in the specification of the present application is appropriately added to the above-described configuration, i.e., even in the case where any other configuration that is not referred to as the above-described configuration but has been described in the specification of the present application is added as appropriate.

### Variations of Above-Described Embodiments

The embodiments described above may in some cases describe features such as the quality, material, size, and shape of each constituent element, the relationship of relative positions of constituent elements, and conditions to implement the present disclosure. However, all of these features are one example in every aspect and are not intended to be limited thereto.

Accordingly, an unlimited number of variations and equivalents that are not described as examples are assumed to fall within the scope of the technique disclosed in the specification of the present application. For example, the scope of the technique is assumed to include cases such as where at least one constituent element is modified, added, or omitted and where at least one constituent element in at least one embodiment is extracted and combined with a constituent element described in a different embodiment.

In the case where features such as the name of a material are described with no particular specification in at least one of the embodiments described above, the material is assumed to include any other additive such as an alloy as long as no contradiction arises.

### EXPLANATION OF REFERENCE SIGNS

3 drift layer, 4 base region, 5 source region, 6 gate trench, 7 gate insulating film, 8 gate electrode, 11 source electrode, 16 terminal trench, 18 gate line, 20 active area, 26 gate trench, 30 termination area, 34 gate contact, 87 gate insulating film, 97 gate insulating film, 100 semiconductor device, 101 semiconductor device, 102 semiconductor device, 103 semiconductor device, 108 region, 109 region, 1000 region.

1. A semiconductor device comprising:
a drift layer of a first conductivity type;
a base region of a second conductivity type provided in a surface layer of the drift layer;
a plurality of source regions of the first conductivity type provided in a surface layer of the base region;
at least one trench extending from an upper surface of the drift layer through the base region to an inside of the drift layer;
a protective layer of the second conductivity type provided in the drift layer located under the trench;
a gate insulating film provided along an inside of the trench including an upper corner portion of the trench;
a gate electrode provided at least in the trench and surround by the gate insulating film;
a source electrode electrically connected to the source regions located adjacent to the trench; and
a gate line provided on an upper surface of the gate electrode provided in the trench,
wherein, among regions partitioned in the trench in plan view, a region where the source electrode is provided is defined as a first region, and a region where the gate line is provided is defined as a second region, and
the gate insulating film provided on the upper corner portion of the trench in the second region has a greater radius of curvature than the gate insulating film provided on the upper corner portion of the trench in the first region.

2. The semiconductor device according to claim 1, wherein
the gate line is provided on the upper surface of the gate electrode extending to upper surfaces of the source regions.

3. The semiconductor device according to claim 2, wherein
the gate line is connected via a plurality of contact holes to the upper surface of the gate electrode extending to the upper surfaces of the source regions.

4. The semiconductor device according to claim 1, wherein
the gate insulating film provided in the trench in the first region and the gate insulating film provided in the trench in the second region have an equal thickness.

5. The semiconductor device according to claim 1, wherein
the trench includes a plurality of trenches,
at least one of the trenches is provided in each of an active area and a termination area
that surrounds the active area in plan view, and the gate electrode provided in the trench in the termination area is not electrically connected to the source electrode and the gate line.

6. The semiconductor device according to claim 1, wherein
the trench incudes a plurality of trenches,
the plurality of the trenches are aligned in stripes in plan view, and
the gate line is provided across the upper surface of the gate electrode provided in each of the plurality of trenches.

7. The semiconductor device according to claim 1, wherein
the trench includes a plurality of trenches,
at least one of the trenches is provided in each of an active area and a termination area that surrounds the active area in plan view, the trenches provided in the active area and the termination area being spaced from each other, and
the trench in the termination area is formed wider than the trench in the active area.

8. The semiconductor device according to claim 1, wherein
the trench includes a plurality of trenches,
at least one of the trenches is provided in an active area surrounded by a termination area in plan view, and
the gate insulating film provided in the trench located in a boundary portion between the active area and the termination area has a greater thickness than the gate insulating film provided in the trench located in the active area and the termination area other than the boundary portion.

9. The semiconductor device according to claim 1, wherein
the trench includes a plurality of trenches,
at least one of the trenches is provided in an active area surrounded by a termination area in plan view, and
the protective layer provided under the trench located in a boundary portion between the active area and the termination area has a lower impurity concentration than the protective layer provided under the trench located in the active area and the termination area other than the boundary portion.

10. A method of manufacturing a semiconductor device, the method comprising:
providing a base region of a second conductivity type in a surface layer of a drift layer of a first conductivity type;
providing a plurality of source regions of the first conductivity in a surface layer of the base region;
providing at least one trench that extends from an upper surface of the drift layer through the base region to an inside of the drift layer;
providing a protective layer of the second conductivity type in the drift layer located under the trench;
defining regions partitioned in the trench in plan view as a first region and a second region;
etching an upper corner portion of the trench in the first region and the second region,
etching the upper corner portion of the trench in the second region;
providing a gate insulating film along an inside of the trench including the upper corner portion of the trench;
providing a gate electrode in the trench surrounded by the gate insulating film;
providing a source electrode that is electrically connected to the source regions located adjacent to the trench in the first region; and
providing a gate line on an upper surface of the gate electrode provided in the trench in the second region,
wherein the gate insulating film provided on the upper corner portion of the trench in the second region has a greater radius of curvature than the gate insulating film provided on the upper corner portion of the trench in the first region.
